(19) United States
(12) Patent Application Publication
(10) Pub. No.: US 2025/0253208 A1
(43) Pub. Date: Aug. 7, 2025

(54) INTEGRATED MULTI-LEVEL COOLING ASSEMBLIES FOR ADVANCED DEVICE PACKAGING AND METHODS OF MANUFACTURING THE SAME

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US); Patrick J. Variot, Los Gatos, CA (US); Hong Shen, Palo Alto, CA (US)

(21) Appl. No.: 18/789,445

(22) Filed: Jul. 30, 2024

Related U.S. Application Data
(60) Provisional application No. 63/575,164, filed on Apr. 5, 2024.
(60) Provisional application No. 63/550,739, filed on Feb. 7, 2024.

(51) Int. Cl. H01L 23/473; H01L 23/00; H01L 23/498; H01L 25/065

(52) U.S. Cl. CPC H01L 23/473; H01L 23/49816; H01L 25/0652; H01L 24/16; H01L 24/32; H01L 24/73; H01L 2224/16225; H01L 2224/32225; H01L 2224/73204; H01L 2924/351

(57) ABSTRACT

A device package comprising an integrated cooling assembly. The integrated cooling assembly comprises a first semiconductor device, a cold plate, and a second semiconductor device attached therebetween. The cold plate comprises a manifold attached to the second semiconductor device. The manifold comprising an inlet opening and an outlet opening, a support feature extending downwardly from the manifold to the first semiconductor device, and a coolant channel coupling the inlet opening and the outlet opening. The coolant channel extends through a portion of the support feature proximate to the first semiconductor device.

### CROSS-REFERENCE TO RELATED APPLICATIONS

This application claims priority to U.S. Provisional Patent Application No. 63/550,739, filed Feb. 7, 2024 and U.S. Provisional Patent Application No. 63/575,164, filed Apr. 5, 2024. The disclosures of each referenced application are hereby incorporated by reference herein in their entireties.

### FIELD

The present disclosure relates to advanced packaging for microelectronic devices, and in particular, embedded cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling, since even small increases in operating temperatures can negatively impact the performance of microprocessors, memory devices, and other electronic components. While some of this energy is expended to operate the cooling systems that are directly cooling the chips (e.g., heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high performance chips in server racks, and each of those high performance chips is a heat source. An uncontrolled ambient temperature in a data center will adversely affect the performance of the individual chips, and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc., have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and amount of remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s), and (ii) the thermal resistance of a thermal interface material(s) itself can inhibit heat transfer from the chip to the heat dissipation devices, undesirably reducing the cooling efficiency of the cooling system.

Such cooling systems can suffer from reduced cooling efficiency due to the design and manufacture of system components. Further, traditional systems lack the ability to cool chips that are located at different levels (e.g., different heights in the Z-axis direction) within a stack. The physical separation between the bottom surfaces of the heat dissipation devices (e.g., heat spreader) and the top surface(s) of the chips (and dummy dies) is typically filled with thick thermal interface material (TIM).

For example, in a three-dimensional integrated circuit (3D-IC), chips that are located farther from the cooling system often experience significantly reduced cooling compared to chips located closer to the cooling system.

Accordingly, there exists a need in the art for improved energy-efficient cooling systems and methods of manufacturing the same.

### SUMMARY

Embodiments herein provide integrated cooling assemblies embedded in advanced device packages. Advantageously, the integrated cooling assemblies provide increased cooling to chips located at different levels (e.g., different heights in the Z-axis direction) within a device package.

One general aspect includes a device package including an integrated cooling assembly. The integrated cooling assembly includes a first semiconductor device, a cold plate, and a second semiconductor device attached therebetween. The cold plate includes a manifold attached to the second semiconductor device. The manifold includes an inlet opening and an outlet opening. A support feature extends downwardly from the manifold to the first semiconductor device. The manifold further includes a coolant channel coupling the inlet opening and the outlet opening. The coolant channel extends through a portion of the support feature proximate to the first semiconductor device.

Implementations of the device package may include one or more of the following features. The support feature may be a portion of a reconstituted wafer or a dummy die. In some embodiments, having the coolant channel extend through the support feature proximate to the semiconductor device allows for heat to be transferred away from the semiconductor device despite the semiconductor device being separated from the coolant source (e.g., heat exchanger or chiller). The second semiconductor device may be part of a reconstituted wafer and may be surrounded by molding (e.g., epoxy or inorganic dielectric like silicon oxide) during the reconstitution process. The portion of the manifold of the cold plate may comprise an additional inlet opening, and an additional outlet opening allowing coolant fluid to flow. In some embodiments, the coolant fluid is received (e.g., via the additional inlet opening) from the same coolant source described above and is then transferred back (e.g., via the additional outlet opening) to said coolant source. The portion of the manifold of the cold plate may comprise an additional coolant channel coupling the additional inlet opening and the additional outlet. The additional coolant channel may also be proximate to the second semiconductor device.

In some embodiments, having the coolant channels extend through the support features proximate to both the semiconductor devices allows for heat to be transferred away from the semiconductor devices despite the semiconductor devices being separate distances away from the coolant source (e.g., heat exchanger or chiller).

Implementations of the device package may include one or more of the following features. In some embodiments, the first coolant channel is coupled to the second coolant channel. For example, the first coolant channel may be coupled between the first inlet opening and the second coolant channel, and the second coolant channel may be coupled between the first coolant channel and the first outlet opening. The device package may further comprise a first inlet opening, a second inlet opening, a first outlet opening, and a second outlet opening. For example, the first coolant channel may couple the first inlet opening to the first outlet opening, and the second coolant channel may couple the second inlet opening to the second outlet opening. In some embodiments, the first coolant channel and the second coolant channel receive and send coolant fluid to the same coolant source. In some embodiments, the first coolant channel and the second coolant channel receive and send coolant fluid to different coolant sources.

Another general aspect includes a device package including a cold plate defining a first level. The cold plate cold plate includes at least two openings. The cold plate further includes a first section of a coolant channel coupled to a first opening of the at least two openings. The cold plate further includes a second section of the coolant channel coupled to a second opening of the at least two openings. The device package further includes a first semiconductor device defining a second level vertically adjacent to the first level. A reconstituted dielectric is disposed laterally adjacent to the first semiconductor device in the second level. A third section of the coolant channel extends through the reconstituted dielectric. The third section of the coolant channel is coupled to the first section of the coolant channel. A portion of the third section of the coolant channel is proximate to a second semiconductor device.

Implementations of the device package may include one or more of the following features. The device package may further include a third level vertically adjacent to the second level, wherein the second level is between the first level and the third level. The third level may comprise the second semiconductor device. The third level also comprises additional molding around the second semiconductor device.

Another general aspect includes a method of manufacturing the device package. The method comprises directly bonding a first substrate comprising the cold plate of any previous aspects to a second substrate comprising first and second vertically stacked semiconductor devices. The method further comprises singulating an integrated cooling assembly comprising the semiconductor devices and the cold plate from the bonded first and second substrates.

### BRIEF DESCRIPTION OF THE DRAWINGS

The above and other objects and advantages of the disclosure will be apparent upon consideration of the following detailed description, taken in conjunction with the accompanying drawings, in which:

FIG. 1A is a schematic plan view of an example of a system panel, in accordance with some embodiments of the present disclosure;

FIG. 1B is a schematic partial sectional side view of a device package mounted on a PCB, in accordance with some embodiments of the present disclosure;

FIG. 1C is a schematic exploded isometric view of the device package in FIG. 1B, in accordance with some embodiments of the present disclosure;

FIG. 2 is a schematic sectional view of an example device package, in accordance with some embodiments of the present disclosure;

FIG. 3 is a schematic partial sectional side view of an integrated cooling assembly, in accordance with some embodiments of the present disclosure;

FIG. 4 is another schematic partial sectional side view of an integrated cooling assembly, in accordance with some embodiments of the present disclosure;

FIG. 5 is another schematic partial sectional side view of an integrated cooling assembly, in accordance with some embodiments of the present disclosure;

FIG. 6 is another schematic partial sectional side view of an integrated cooling assembly, in accordance with some embodiments of the present disclosure;

FIG. 7 is another schematic partial sectional side view of an integrated cooling assembly, in accordance with some embodiments of the present disclosure;

FIG. 8 is another schematic partial sectional side view of an integrated cooling assembly, in accordance with some embodiments of the present disclosure;

FIG. 9 is another schematic partial sectional side view of an integrated cooling assembly, in accordance with some embodiments of the present disclosure;

FIG. 10 is another schematic partial sectional side view of an integrated cooling assembly, in accordance with some embodiments of the present disclosure;

FIGS. 11A-11F are schematic partial sectional side views showing a process for manufacturing the integrated cooling assemblies described herein, in accordance with some embodiments of the present disclosure;

FIGS. 12A-12F are schematic partial sectional side views showing another process for manufacturing the integrated cooling assemblies described herein, in accordance with some embodiments of the present disclosure;

FIGS. 13A-13F are schematic partial sectional side views showing another process for manufacturing the integrated cooling assemblies described herein, in accordance with some embodiments of the present disclosure;

FIG. 14 shows a method that can be used to manufacture the integrated cooling assemblies, in accordance with some embodiments of the present disclosure;

FIG. 15 is another schematic partial sectional side view of an integrated cooling assembly, in accordance with some embodiments of the present disclosure;

FIG. 16 illustrates a device package with an external heat sink, in accordance with some embodiments of the present disclosure; and

FIG. 17 is a schematic sectional view of an integrated cooling assembly of the device package, in accordance with embodiments of the present disclosure.

The figures herein depict various embodiments of the present disclosure for purposes of illustration only. It will be appreciated that additional or alternative structures, assemblies, systems, and methods may be implemented within the principles set out by the present disclosure.

### DETAILED DESCRIPTION

Embodiments herein provide integrated cooling assemblies embedded in advanced device packages. The integrated cooling assemblies provide increased cooling to chips located at different levels (e.g., different heights in the Z-axis direction) within a device package. For example, by vertically stacking two semiconductor devices having different widths, an exposed surface of the wider semiconductor device and an exposed surface of the narrower semiconductor device may both be exposed to cooling fluid, as discussed in more detail below. Advantageously, by exposing portions of both device surfaces to cooling fluid, the efficiency at which the stacked devices are cooled is increased.

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term “substrate” also includes semiconductor substrates that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” (e.g., the side on which semiconductor device elements (e.g., transistors, resistors, capacitors, etc.) are fabricated), and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that forms the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal (e.g., after substrate thinning operations). Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom,” and the like are generally made with reference to the X, Y, and Z directions set forth by X, Y and Z axes in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” and the like, either alone or in combination with a spatially relevant term, include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds.” In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding (e.g., direct dielectric bonding) provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Unless otherwise noted, the terms “cooling assembly” and “integrated cooling assembly” generally refer to a semiconductor device and a cold plate attached to the semiconductor device. Typically, the cold plate is formed with recessed surfaces that define one or more fluid cavities (e.g., coolant chamber volume(s) or coolant channels) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. The cold plate may comprise a polymer material.

The cold plate may be attached to the semiconductor device by use of a compliant adhesive layer or by direct bonding or hybrid bonding. For example, the cold plate may include material layers and or metal features that facilitate direct bonding or hybrid bonding with the semiconductor device. Beneficially, the backside of the semiconductor device is directly exposed to coolant fluid flowing through the integrated cooling assembly, thus providing for direct heat transfer therebetween. Unless otherwise noted, the integrated cooling assemblies described herein may be used with any desired fluid (e.g., liquid, gas, and/or vapor-phase coolants), such as water, glycol, etc. Direct bonding may include direct dielectric bonding techniques as described herein, and may give rise to direct dielectric bonds. Hybrid bonding may include hybrid bonding techniques as described herein, and may give rise to direct hybrid bonds.

Exemplary fluids available for use in the various thermal solution embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Additionally, depending upon design and operating conditions, these fluids may be used in single-phase liquid, single-phase vapor, two-phase liquid/vapor or two-phase solid/liquid. All of these fluids and fluid mixtures will alter the thermohydraulic and heat transfer properties by altering the temperatures where phase change occurs, as well as meeting design temperature and pressure conditions for the component being cooled or warmed and the thermal solution being deployed. Additionally, multiple combinations of the fluid phases may be employed in various hybrid configurations to meet the particular cooling or warming needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a thermal solution system using the disclosed embodiments, engineered dielectric cooling fluids may be used. Some examples of dielectric fluids used for cooling semiconductors include: 3M™ Fluorinert™ Liquid FC-40—A non-flammable, dielectric fluid that can be used in direct contact with live electronics; 3M™ Novec™ Engineered Fluids—A non-flammable, dielectric fluid that can be used in direct contact with live electronics; Galden® PFPE (perfluoropolyether) products used as heat transfer fluids; EnSolv Fluoro HTF—A solvent with a high boiling point and low pour point that can be used for semiconductor wafer cooling. It is understood that in the selection of the cooling fluid, system design aspects such as operating temperatures and pressures, fluid flow rates, fluid viscosity, and other properties will require evaluation when selecting the appropriate cooling fluid.

In some embodiments, the cooling fluids may contain microparticles and/or nanoparticle additives to enhance the conductivity of the cooling fluid within the integrated cooling assemblies. Choi and Eastman (1995) from Argonne National Laboratory, U.S.A. (Yu et al., 2007) coined the word “nanofluid.” Nanofluids are engineered fluids prepared by suspending the nano-sized (1-100 nm) particles of metals/non-metals and their oxide(s) with a base/conventional fluid. The suspension of high thermal conductivity metals/non-metals and their oxides nanoparticles enhances the thermal conductivity and heat transfer ability, etc. of the base fluid. The additives to the underlying cooling fluid may comprise for example, nanoparticles of carbon nanotube, nanoparticles of graphene, or nanoparticles of metal oxides. When the cooling fluid contains microparticles, the microparticles are typically 10 microns or less in diameter. Silicon oxide microparticles may be used.

The volume concentration of these micro or nanoparticles may be less than 1%, less than 0.2%, or less than 0.05%. Depending upon the liquid and micro/nanoparticle type chosen for the cooling fluid, higher volume concentrations of 10% or less, 5% or less, or 2% or less may be used. The cooling fluids may also contain small amounts of glycol or glycols (e.g., propylene glycol, ethylene glycol etc.) to reduce frictional shear stress and drag coefficient in the cooling fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au, etc.), metal oxides (e.g., TiO₂, Al₂O₃, CuO, etc.), carbons (e.g. CNTS, graphene, diamond, graphite . . . etc.), or a mixture of different types of nanomaterials. Metal nanoparticles (Cu, Ag, Au . . . ), metal oxide nanoparticles (Al₂O₃, TiO₂, CuO), and carbon-based nanoparticles are commonly employed elements. Silicon oxide nanoparticles may also be used. Using cooling fluids with micro and/or nanoparticles when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nanoparticles. Magnetic nanoparticles may be coated with surfactant layers such as oleic acid to reduce particle agglomeration and/or settling. Magnetic nanoparticles used in MNFs are usually made of metal materials (ferromagnetic materials) such as iron, nickel, cobalt, as well as their oxides such as spinel-type ferrites, magnetite (Fe₃O₄), and so forth. The magnetic nanoparticles used in MNFs typically range in size from about 1 to 100 nanometers (nm).

A reconstituted wafer is taken to be a wafer comprising dies, die interconnects, and a dielectric (e.g., organic dielectric (e.g., silicon oxide, silicon nitride, etc.) and/or inorganic dielectrics (e.g., molding compound, resin, etc.). For example, a semiconductor wafer may be singulated into dies, and a dielectric material may be disposed around the dies to form a reconstituted wafer. The dies may be arranged in a layout according to a desired spacing between the dies. Reconstituting dies to form a reconstituted wafer allows dies previously singulated from a wafer to be molded into a new wafer (i.e., a reconstituted wafer).

A dummy die may comprise a non-operational die, filler (encapsulant) material, a portion of a reconstituted wafer, a blank carrier, and/or the like.

“Proximate” is taken to mean either adjacent or directly adjacent. For example, a coolant channel (or section of a coolant channel) that is proximate to a semiconductor device may be adjacent to at least a portion of a surface of the semiconductor device, but not in direct contact with the semiconductor device. Alternatively, a coolant channel (or a section of a coolant channel) that is proximate to a semiconductor device may be directly adjacent to at least a portion of a surface of the semiconductor device, such that a portion of the coolant channel (or coolant fluid flowing through the coolant channel) is in direct contact with the surface of the semiconductor device.

This disclosure describes embodiments involving the architecture of system and component elements that can be employed to provide for the cooling of semi-conductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

In some embodiments, a cooling channel is a liquid cooling channel, and a liquid may flow through the liquid cooling channel. In some embodiments, the liquid may comprise a water and/or glycol (e.g., propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

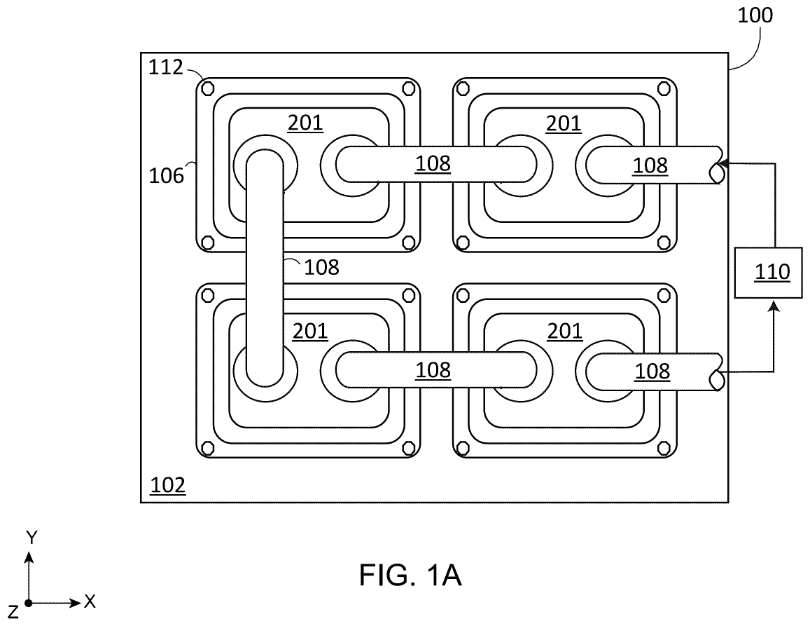

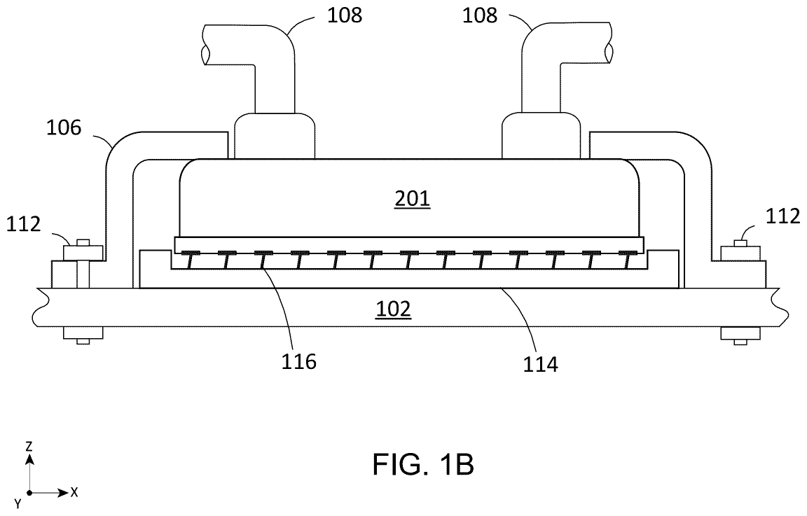

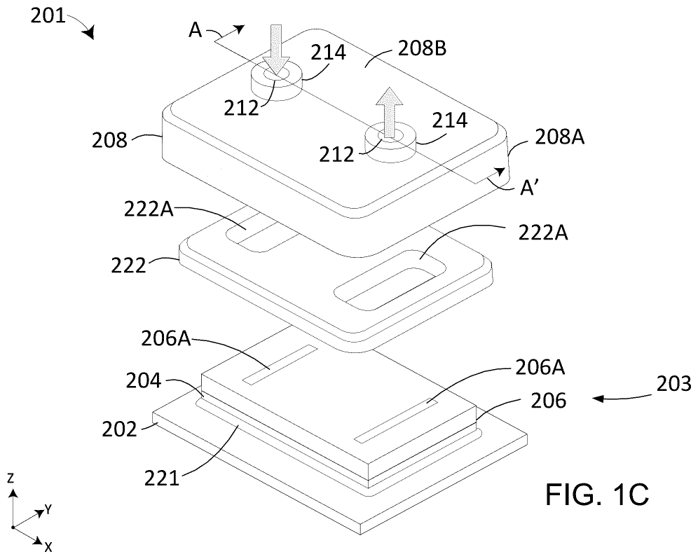

FIG. 1A is a schematic plan view of an example of a system panel 100, in accordance with some embodiments of the present disclosure. Generally, the system panel 100 includes a printed circuit board (PCB) 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase (e.g., liquid, vapor, gas, or combinations thereof) and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel, and the coolant source 110 may include or further include a compressor (not shown) for condensing the received vapor to a liquid form.

FIG. 1B is a schematic partial sectional side view of a portion of the system panel 100 of FIG. 1A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112 (e.g., compression screws) collectively configured to exert a relatively uniform downward force on the upward facing edges of the device package 201. The uniform downward force ensures proper pin contact between the device package 201 and the socket 114.

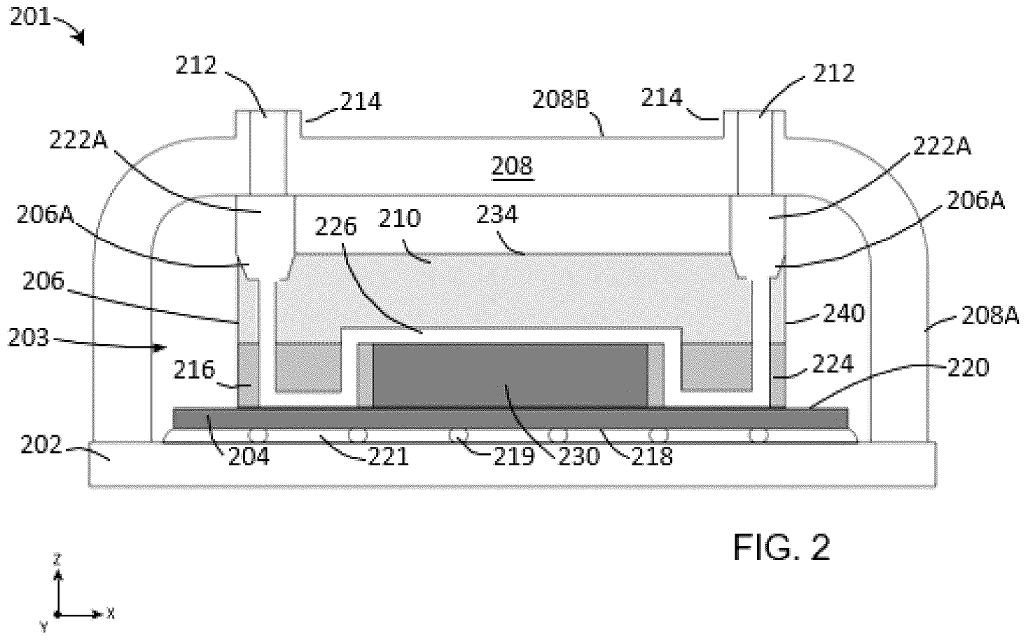

FIG. 1C is a schematic exploded isometric view of an example device package 201, in accordance with some embodiments of the present disclosure. FIG. 2 is a schematic sectional view of the device package 201 taken along line A-A′ of FIG. 1C. Generally, the device package 201 includes a package substrate 202, an integrated cooling assembly 203 disposed on the package substrate 202, and a package cover 208 disposed on a peripheral portion of the package substrate 202. Suitable materials that may be used in the package cover 208 include copper, aluminum, metal alloys, etc. The package cover 208 extends over the integrated cooling assembly 203 so that the integrated cooling assembly 203 is disposed between the package substrate 202 and the package cover 208. The integrated cooling assembly 203 typically includes a semiconductor device 204 and a cold plate 206 bonded to the semiconductor device 204. In some embodiments, the cold plate 206 may comprise substrate material like silicon, glass, ceramic, etc. Although the lateral dimensions (or footprint) of the cold plate 206 are shown to be the same or similar to the lateral dimensions (or footprint) of the semiconductor device 204, the footprint of the cold plate 206 may be smaller or larger in one or both directions when compared to the footprint of the semiconductor device 204.

As shown, the device package 201 further includes a sealing material layer 222 that forms a coolant fluid impermeable barrier between the package cover 208 and the integrated cooling assembly 203 that prevents leaking of the coolant fluid outside of the cooling assembly and prevents coolant fluid from reaching an active side 218 of the semiconductor device 204 and causing damage thereto. Coolant is delivered to the integrated cooling assembly 203 via inlet/outlet openings 212 in the package cover 208 and corresponding openings 222A formed through the sealing material layer 222. In some embodiments, the sealing material layer 222 comprises an adhesive material that reliably attaches the package cover 208 to the integrated cooling assembly 203.

In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g., solder. In other embodiments, the sealing material layer 222 is formed from a molding compound, e.g., a thermoset resin, that when polymerized, forms a hermetic seal between the package cover 208 and the cold plate 206. Here, the coolant fluid is delivered to the cold plate 206 through openings 222A disposed through the sealing material layer 222. As shown, the openings 222A are respectively in registration and fluid communication with inlet and outlet openings 212 of the package cover 208 thereabove and inlet and outlet openings 206A in the cold plate 206 therebelow.

It will be understood that the openings are shown in a section view. The openings may have any cross-sectional shape that allows fluid to flow therethrough (e.g., rectangular, square, hexagonal or circular cross-sections). For example, the inlet and outlet openings 206A of the cold plate 206 may form an elongated shape extending from one side of the cold plate 206 to another side of the cold plate 206. For example, the inlet and outlet openings 206A may form any shape having a length greater than a width in the X-Y plane (e.g., a rectangular or a trapezoidal shape). A shape in the X-Y plane of the openings 222A disposed through the sealing material layer 222 may be substantially the same as the shape of the inlet and outlet openings 206A of the cold plate 206 in the same place. Furthermore, it will be understood that all references to an opening throughout the present disclosure refer to an opening defined by a sidewall (e.g., opening sidewall).

Generally, the package substrate 202 includes a rigid material, such as an epoxy or resin-based laminate, that supports the integrated cooling assembly 203 and the package cover 208. The package substrate 202 may include conductive features disposed in or on the rigid material that electrically couples the integrated cooling assembly 203 to a system panel, such as the PCB 102.

FIG. 2 is a schematic sectional view of an example device package, in accordance with some embodiments of the present disclosure. The integrated cooling assembly 203 typically includes one or more semiconductor devices (e.g., a first device 204) and a cold plate 206. Here, a second device 230 is bonded to the first device 204, and the cold plate 206 is bonded to the first device 204 and the second device 230. The first device 204 may include an active side 218 that includes device components (e.g., transistors, resistors, capacitors, etc.) formed thereon or therein, and a non-active side, here the device backside 220, opposite the active side 218. As shown, the active side 218 is positioned adjacent to and facing towards the substrate 202. The active side 218 may be electrically connected to the package substrate 202 by use of conductive bumps 219, which are encapsulated by a first underfill layer 221 disposed between the first device 204 and the package substrate 202. The first underfill layer 221 may comprise a cured polymer resin or epoxy, which provides mechanical support to the conductive bumps 219 and protects against thermal fatigue. In some embodiments, the active side 218 may be electrically connected to another package substrate (e.g. PCB), another active die, or another passive die (e.g. Si or glass interposer), a reconstituted substrate, etc. using hybrid bonding or conductive bumps 219. The cold plate 206 may be disposed above the package substrate 202 with the first device 204 attached to the package substrate 202. For example, the first device 204 and/or the second device 230 may be disposed between the cold plate 206 and the package substrate 202.

In some embodiments, the second device 230 includes the same or similar components as the first device 204. For example, the second device 230 may have an active side positioned adjacent to and facing the first device 204 and a non-active side opposite the active side. The second device 230 may be attached to the first device 204 (e.g., using hybrid bonding) to form interconnections, such that electronic signals may pass between the first device 204 and the second device 230. Although the above description suggests that the active side 218 of first device 204 and the active side of second device 230 are facing the package substrate 202, in some embodiments, the active side of one or both the dies may be facing away from the package substrate 202.

As shown, a width of the second device 230 in the X-axis direction is less than a width of the first device 204 in the X-axis direction. By providing the narrower device on top of the wider device, a portion of the backside 220 of the first device 204 remains exposed after stacking, such that a coolant channel 226 may be disposed adjacent to at least portions of both the first and second devices 204, 230. The overall efficiency at which both devices are cooled is thereby increased. In particular, heat flux may flow at a greater rate from the exposed surfaces of the first device 204 compared to a rate of flow of heat flux at the bonding interface between the first and second devices 204, 230. In some embodiments, a width of the second device 230 in the Y-axis direction can be less that, the same as, or larger than a width of the first device 204 in the Y-axis direction

In some embodiments, the cold plate 206 comprises a manifold 210, a first support feature 216, a second support feature 224 and/or one or more coolant channels 226. The manifold 210 may be formed of a polymer or epoxy molding material, and/or a compliant adhesive layer, such as a TIM layer. In some embodiments, the manifold 210 is formed from a molding compound (e.g., a thermoset resin) that forms a hermetic seal between one or more coolant channels 226 and the package cover 208. In some embodiments, the manifold 210 is a carrier substrate that provides support for a thinning operation and/or for a thinned material to facilitate substrate handling during one or more of the manufacturing operations described herein. In some embodiments, the manifold 210 functions as a heat spreader that redistributes heat from the first device 204 and/or the second device 230. In some embodiments, the manifold 210 comprises one or more openings. For example, FIG. 2 displays the manifold 210 having openings 206A. In some embodiments, the openings 206A are in fluid communication with the inlet/outlet openings 212 of the package cover 208 through openings 222A formed in the sealing material layer 222 disposed therebetween.

In some embodiments, the first support feature 216 and the second support feature 224 are dummy dies, or parts of dummy dies, that are bonded to the first device 204. A dummy die may comprise a non-operational die, filler (organic or inorganic encapsulant) material, a portion of a reconstituted wafer, a blank carrier, and/or the like. In some embodiments, one or more support features and the second device 230 are bonded to the first device 204 (which may be a wafer or a reconstituted wafer) and one or more spaces between the one or more support features and the second device 230 are filled using organic or inorganic dielectric material. In some embodiments, coolant channels (e.g., the coolant channel 226) are formed within the first support feature 216 and/or the second support feature 224 after the one or more spaces between the one or more support features and the second device 230 are filled using organic or inorganic dielectric material. Although two support features are shown, the cold plate 206 may comprise more or fewer support features. For example, the cold plate 206 may comprise only one support feature. In another example, the cold plate 206 may comprise zero support features. In another example, the cold plate 206 may comprise ten support features.

In some embodiments, the manifold 210, the first support feature 216, and/or the second support feature 224 may comprise one or more sections of one or more coolant channels 226. For example, FIG. 2 displays a single coolant channel 226, and the manifold 210, the first support feature 216, and the second support feature 224 each comprise one or more sections of the coolant channel 226. As shown, the manifold 210 comprises a first section of the coolant channel 226 that may couple an opening 206A to a second section of the coolant channel 226 formed within the first support feature 216. The second section of the coolant channel 226 may couple the first section of the coolant channel 226 to a third section of the coolant channel 226 formed within the manifold 210. A portion of the second section of the coolant channel 226 may be proximate to the backside 220 of the first device 204 to facilitate thermal dissipation. In some embodiments, the backside 220 of the first device 204 is directly exposed to coolant fluids flowing through the portion of the second section of the coolant channel 226 proximate to the backside 220 of the first device 204. In some embodiments, there is a thin barrier (e.g., a lower portion of the first support feature 216) between the portion of the second section of the coolant channel 226 and the backside 220 of the first device 204 preventing direct contact between the coolant fluids and the backside 220 of the first device 204.

The third section of the coolant channel 226 may couple the second section of the coolant channel 226 to a fourth section of the coolant channel 226 formed within the second support feature 224. A portion of the third section of the coolant channel 226 may be proximate to the backside of the second device 230 to facilitate thermal dissipation. In some embodiments, the backside of the second device 230 is directly exposed to coolant fluids flowing through the portion of the third section of the coolant channel 226 proximate to the backside of the second device 230. In some embodiments, there is a thin barrier (e.g., a lower portion of the manifold 210) between the portion of the third section of the coolant channel 226 and the backside of the second device 230 preventing direct contact between the coolant fluids and the backside of the second device 230.

The fourth section of the coolant channel 226 may couple the third section of the coolant channel 226 to a fifth section of the coolant channel 226 formed within the manifold 210. A portion of the fourth section of the coolant channel 226 may be proximate to the backside 220 of the first device 204 to facilitate thermal dissipation. In some embodiments, the backside 220 of the first device 204 is directly exposed to coolant fluids flowing through the portion of the fourth section of the coolant channel 226 proximate to the backside 220 of the first device 204. In some embodiments, there is a thin barrier (e.g., a lower portion of the second support feature 224) between the portion of the fourth section of the coolant channel 226 and the backside 220 of the first device 204 preventing direct contact between the coolant fluids and the backside 220 of the first device 204. The manifold 210 may also comprise the fifth section of the coolant channel 226 that may couple an opening 206A to the fourth section of the coolant channel 226 formed within the second support feature 224.

The cold plate 206 may be attached to the backside 220 of the first device 204 and/or the second device 230 without the use of an intervening adhesive material (e.g., the cold plate 206 may be directly bonded to the backside 220 of the first device 204 and/or the backside of the second device 230), such that the cold plate 206 and the backsides of the devices are in direct thermal contact. For example, sidewalls of the first and second support features 216, 224 (and optional lower surfaces of first and second support features 216, 224) may extend downwardly from the manifold 210 to the backside 220 of the first device 204 to attach the cold plate 206 to the first device 204. Furthermore, a lower surface of the manifold between the first and second support features 216, 224 may be attached to the backside of the second device 230.

In some embodiments, the cold plate 206 comprises a top portion 234 and a sidewall 240 (e.g., a perimeter sidewall defining a perimeter of the cold plate 206) extending downwardly from the top portion 234 to the backside 220 of the first device 204. The top portion 234, the perimeter sidewall 240, and the backside 220 of the first device 204 collectively define one or more coolant channel 226 therebetween. In some embodiments, the cold plate 206 comprises cavity dividers extending downwardly from the top portion 234 towards the backsides of the first device 204 and/or the second device 230. The cavity dividers may extends laterally and in parallel between an inlet opening 206A of the cold plate 206 and an outlet opening 206A of the cold plate 206 to define one or more coolant channels 226 therebetween. It should be appreciated that, the cold plate 206 may comprise one cavity divider which forms two coolant channels by means of the cavity divider and portions of the perimeter sidewall 240. Alternatively, in other embodiments, the cold plate 206 may comprise plural cavity dividers, for example two cavity dividers, five cavity dividers, or six cavity dividers. In such examples, the cold plate 206 comprises more than two coolant channels, for example three coolant channels, four coolant channels, seven coolant channels, or more, defined between the cavity dividers and/or the cavity divider(s) and the perimeter sidewall 240.

In some embodiments, the cavity dividers comprise cavity sidewalls which form surfaces of corresponding coolant channels. In embodiments where plural cavity dividers extend in parallel to each other, cavity sidewalls of adjacent cavity dividers are opposite (e.g., facing) each other. In embodiments comprising a single cavity divider, a first cavity sidewall may be opposite (e.g., face) a first portion of the perimeter sidewall 240 extending parallel to and facing the first cavity sidewall. A second cavity sidewall may be opposite (e.g., face) a second portion of the perimeter sidewall 240 extending parallel to and facing the second cavity sidewall. The first portion of the perimeter sidewall 240 may be an opposite side of the cold plate 206 to the second portion of the perimeter sidewall 240. For example, in embodiments where the cold plate 206 is rectangular, first and second opposing sides of the rectangular cold plate 206 form the first and second portions of the perimeter sidewall 240.

The cavity dividers may be continuous cavity dividers which extend continuously (e.g., in the Y-axis direction) between the inlet opening 206A and the outlet opening 206A of the cold plate 206. In some embodiments, the cavity sidewalls are formed at an acute angle with respect to the backside of the first device 204 and/or the second device 230 such that upper portions of opposing (e.g., facing) cavity sidewalls meet. Therefore, the cavity sidewalls and the backside of the first device 204 and/or the second device 230 collectively define a triangular cross-section of the coolant channel 210.

In some embodiments, the backside of the first device 204 and/or the second device 230 comprises a corrosion protective layer (not shown). The corrosion protective layer may be a continuous layer disposed across the entire backside of the first device 204 and/or the second device 230, such that the cold plate 206 is attached thereto. Beneficially, the corrosion protective layer provides a corrosion-resistant barrier layer, thus preventing undesired corrosion of the of the first device 204 and/or the second device 230 (e.g., the semiconductor substrate material which might otherwise be in direct contact with coolant fluid flowing through one or more coolant channels 226).

The package cover 208 generally comprises one or more vertical or sloped sidewall portions 208A and the lateral portion 208B that spans and connects the sidewall portions 208A. The sidewall portions 208A may extend upwardly from a peripheral surface of the package substrate 202 to surround the device 204 and the cold plate 206 disposed thereon. The lateral portion 208B may be disposed over the cold plate 206 and is typically spaced apart from the cold plate 206 by a gap corresponding to the thickness of the sealing material layer 222. Coolant is circulated through the coolant channels 226 through the inlet and outlet openings 212 of the package cover 208 formed through the lateral portion 208B. The inlet and outlet openings 206A of the cold plate 206 may be in fluid communication with the inlet and outlet openings 212 of the package cover 208 through the inlet and outlet openings 222A formed in the sealing material layer 222 disposed therebetween. In certain embodiments, coolant lines 108 (FIGS. 1A-1B) may be attached to the device package 201 by use of connector features formed in the package cover 208, such as threads formed in the sidewalls of the inlet and outlet openings 212 of the package cover 208 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 206 and the first device 204 therebelow. In some embodiments, the package cover 208 is formed of a thermally conductive metal, such as aluminum or copper. In such embodiments, the package cover 208 functions as a heat spreader that redistributes heat from one or more electronic components of the first device 204.

It should be noted that the direction in which the coolant fluid flows through the cold plate 206 may be controlled depending on the relative locations of the inlet and outlet openings. For example, the coolant fluid may flow from left to right in the device package 201 of FIG. 2 when the inlet openings 212, 222A, 206A of the package cover 208, the sealing material layer 222, and the cold plate 206, respectively, are located on the left-hand side of the device package 201 and the outlet openings 212, 222A, 206A of the package cover 208, the sealing material layer 222, and the cold plate 206, respectively, are located on the right-hand side of the device package 201. Alternatively, the coolant fluid may flow from right to left in the device package 201 illustrated in FIG. 2 when the outlet openings 212, 222A, 206A of the package cover 208, the sealing material layer 222, and the cold plate 206 are located on the left-hand side of the device package 201 and the inlet openings 212, 222A, 206A of the package cover 208, the sealing material layer 222, and the cold plate 206 are located on the right-hand side of the device package 201. Although only one set of inlet and outlet openings is shown and described here, additional inlet and outlet openings may also be provided at various locations on the package cover 208, the sealing material layer 222, and the cold plate 206.

One or more coolant chamber volumes and/or coolant channels may extend between a single inlet opening and a single outlet opening of the cold plate 206, such that the coolant chamber volume(s) and/or coolant channel(s) share the same inlet and outlet openings. In some embodiments, multiple inlet and/or outlet openings may be coupled to the coolant chamber volume(s).

In embodiments having plural coolant chamber volumes and/or plural coolant channels, each coolant chamber volume and/or coolant channel may be connected between a separate inlet opening and a separate outlet opening. In such embodiments, coolant fluid may be directed to the separate inlet opening and from the separate outlet openings using a manifold disposed above the openings in the Z-axis direction.

In some embodiments, a height in the Z-axis direction of the coolant chamber volume(s) and or coolant channel(s) may be greater than 100 μm, 100 μm-1000 μm, or 100 μm-700 μm. A width in the Y-axis direction of the coolant chamber volume(s) and/or coolant channel(s) may be greater than 100 μm, 100 μm-1000 μm, or 100 μm-700 μm. For example, the width of the coolant chamber volume(s) and/or coolant channel(s) may be greater than the height. A cross-section of the coolant chamber volume(s) and/or coolant channel(s) in the Y-Z plane is wide enough to allow for a pressure drop of 0-20 psi, 3-15 psi, or 4-10 psi.

In some embodiments, preparing a desired surface roughness of the sidewalls of the coolant chamber volume(s) and/or coolant channels may include depositing an organic layer on a photoresist layer after cold plate features have been etched to form a micro-masking layer, such as between 1 to 30 nm. The micro-masking layer may be dry etched to form the desired surface roughness, such as between 0.1 to 3.0 nm.

In some embodiments, the cold plate 206 is attached to the backside 220 of the first device 204 and/or the second device 230 without the use of an intervening adhesive. For example, the cold plate 206 may be directly bonded to the backside 220 of the first device 204, such that the cold plate 206 and the backside 220 of the first device 204 are in direct contact. For example, in some embodiments, one or both of the cold plate 206 and the backside 220 of the first device 204 may comprise a dielectric material layer and the cold plate 206 is directly bonded to the backside 220 of the first device 204 through bonds formed between one or more dielectric material layers. In some embodiments, one of the cold plate 206 or the backside of the first device 204 and/or the second device 230 may comprise a thin bonding dielectric layer (e.g., silicon nitride, etc.) and other element(s) may not include any such explicit bonding dielectric layer (or can have only a native oxide layer). In some embodiments, one or more material layers may be continuous or non-continuous. For example, a first dielectric material layer may be disposed only on lower surfaces of the cold plate 206 facing the backside 220 of the first device 204.

The cold plate 206 and the semiconductor devices may be formed of CTE matched materials that eliminate the need for an intervening TIM layer. In some embodiments, the integrated cooling assembly 203 and the package cover 208 may be formed of CTE mismatched materials and attached to one another using a flexible material to form the sealing material layer, or by use of a decoupling adhesive layer disposed between the sealing material layer and one of the cold plate or the package cover. The flexible material may absorb the difference in linear expansion between the package cover 208 and the cold plate 206 during repeated thermal cycles to extend the useful lifetime of the device package 201. Although FIG. 2 displays a single coolant channel 226 in contact with the first device 204 and the second device 230, there may be any number of coolant channels and/or coolant channel designs in contact with one or both devices.

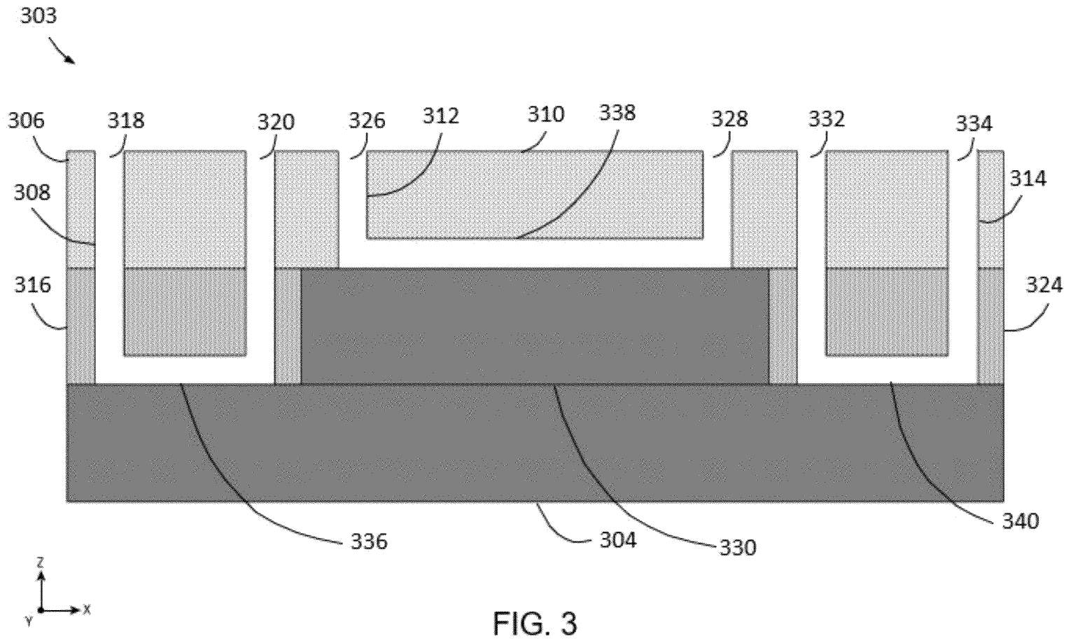

FIG. 3 is a schematic sectional view of at least a portion of an integrated cooling assembly 303 comprising a first coolant channel design. The at least a portion of the integrated cooling assembly 303 comprises a cold plate 306, a first device 304, and a second device 330. Here, the second device 330 is bonded to the first device 304, and the cold plate 306 is bonded to the first device 304 and the second device 330. As described above, the first device 304 and/or the second device 330 may include an active side that includes device components (e.g., transistors, resistors, capacitors, etc.) formed thereon or therein, and a non-active side (e.g., the device backside) opposite the active side. In some embodiments, the cold plate 306 comprises a manifold 310, a first support feature 316, a second support feature 324, a first coolant channel 308, a second coolant channel 312, and a third coolant channel 314.

In some embodiments, the manifold 310 comprises a first opening 318, a second opening 320, a third opening 326, a fourth opening 328, a fifth opening 332, and a sixth opening 334. Although six openings are displayed, more or fewer openings may be used. In some embodiments, one or more openings allow coolant fluid to flow through one or more coolant channels. For example, the first opening 318 and the second opening 320 may allow coolant fluid to flow into and out of the first coolant channel 308. In some embodiments, each of the coolant channels receives coolant fluid from a single coolant source, then transfers the received coolant fluid back to the coolant source. In some embodiments, one or more coolant channels receive coolant fluid from different coolant sources. For example, the first coolant channel 308 may receive coolant fluid from a first coolant source, and the second coolant channel 312 and the third coolant channel 314 may receive coolant fluid from a second coolant source.

In some embodiments, the manifold 310, the first support feature 316, and/or the second support feature 324 each comprise one or more sections of a coolant channel. As shown, the manifold 310 comprises a first section of the first coolant channel 308 that couples the first opening 318 to a second section of the first coolant channel 308 formed within the first support feature 316. The second section of the first coolant channel 308 couples the first section of the first coolant channel 308 to a third section of the first coolant channel 308 formed within the manifold 310. A portion 336 of the second section of the first coolant channel 308 may be proximate to the backside of the first device 304 to facilitate thermal dissipation. In some embodiments, the backside of the first device 304 is directly exposed to coolant fluids flowing through the portion 336 of the second section of the first coolant channel 308 proximate to the backside of the first device 304. In some embodiments, there is a thin barrier between the portion 336 of the second section of the first coolant channel 308 and the backside of the first device 304 preventing direct contact between the coolant fluids and the backside of the first device 304. The manifold 310 may also comprise a third section of the first coolant channel 308 that couples the second opening 320 to the second section of the first coolant channel 308 formed within the first support feature 316.

As shown, the manifold 310 comprises the second coolant channel 312 coupled to the third opening 326 and the fourth opening 328. A portion 338 of the second coolant channel 312 may be proximate to the backside of the second device 330 to facilitate thermal dissipation. In some embodiments, the backside of the second device 330 is directly exposed to coolant fluids flowing through the portion 338 of the second coolant channel 312 proximate to the backside of the second device 330. In some embodiments, there is a thin barrier between the portion 338 of the second coolant channel 312 and the backside of the second device 330 preventing direct contact between the coolant fluids and the backside of the second device 330.

In some embodiments, the manifold 310 comprises a first section of the third coolant channel 314 that couples the fifth opening 332 to a second section of the third coolant channel 314 formed within the second support feature 324. The second section of the third coolant channel 314 couples the first section of the third coolant channel 314 to a third section of the third coolant channel 314 formed within the manifold 310. A portion 340 of the second section of the third coolant channel 314 may be proximate to the backside of the first device 304 to facilitate thermal dissipation. In some embodiments, the backside of the first device 304 is directly exposed to coolant fluids flowing through the portion 340 of the second section of the third coolant channel 314 proximate to the backside of the first device 304. In some embodiments, there is a thin barrier between the portion 340 of the second section of the third coolant channel 314 and the backside of the first device 304 preventing direct contact between the coolant fluids and the backside of the first device 304. The manifold 310 may also comprise a third section of the third coolant channel 314 that couples the sixth opening 334 to the second section of the third coolant channel 314 formed within the second support feature 324.

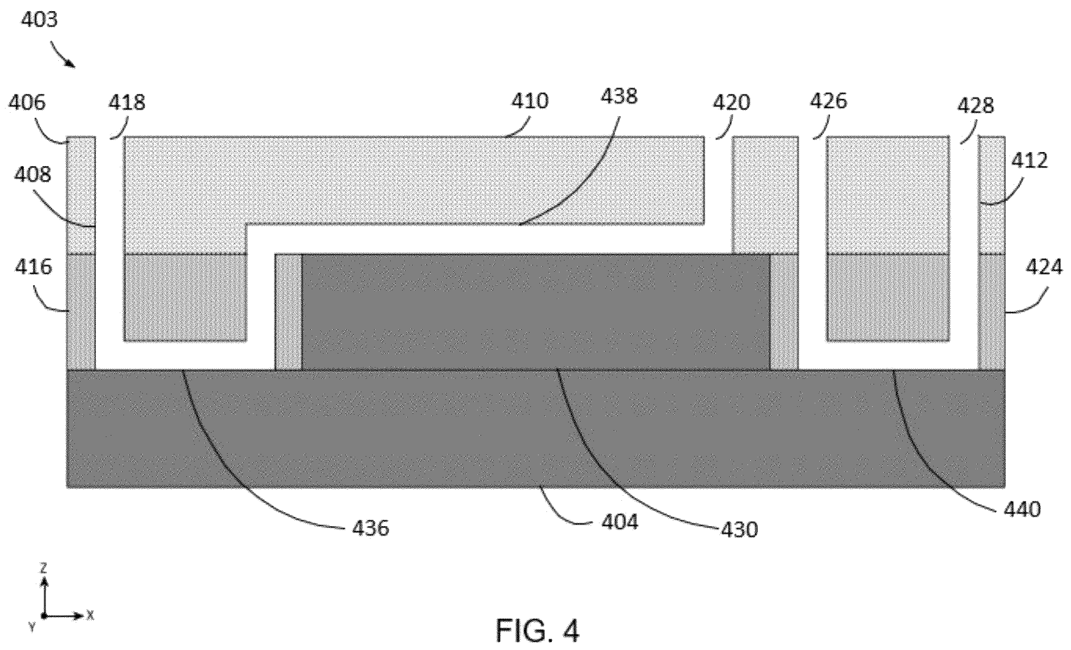

FIG. 4 is a schematic sectional view of at least a portion of an integrated cooling assembly 403 comprising a second coolant channel design. The at least a portion of the integrated cooling assembly 403 comprises a cold plate 406, a first device 404, and a second device 430. Here, the second device 430 is bonded to the first device 404 and the cold plate 406 is bonded to the first device 404 and the second device 430. As described above, the first device 404 and/or the second device 430 may include an active side that includes device components (e.g., transistors, resistors, capacitors, etc.) formed thereon or therein, and a non-active side (e.g., the device backside) opposite the active side. In some embodiments, the cold plate 406 comprises a manifold 410, a first support feature 416, a second support feature 424, a first coolant channel 408, and a second coolant channel 412.

In some embodiments, the manifold 410 comprises a first opening 418, a second opening 420, a third opening 426, and a fourth opening 428. In some embodiments, one or more openings allow coolant fluid to flow through one or more coolant channels. In some embodiments, each of the coolant channels receives coolant fluid from a single coolant source, then transfers the received coolant fluid back to the coolant source. In some embodiments, one or more coolant channels receive coolant fluid from different coolant sources.

In some embodiments, the manifold 410, the first support feature 416, and/or the second support feature 424 each comprise one or more sections of a coolant channel. As shown, the manifold 410 comprises a first section of the first coolant channel 408 that couples the first opening 418 to a second section of the first coolant channel 408 formed within the first support feature 416. The second section of the first coolant channel 408 couples the first section of the first coolant channel 408 to a third section of the first coolant channel 408 formed within the manifold 410. A portion 436 of the second section of the first coolant channel 408 may be proximate to the backside of the first device 404 to facilitate thermal dissipation. In some embodiments, the backside of the first device 404 is directly exposed to coolant fluids flowing through the portion 436 of the second section of the first coolant channel 408 proximate to the backside of the first device 404. In some embodiments, there is a thin barrier between the portion 436 of the second section of the first coolant channel 408 and the backside of the first device 404 preventing direct contact between the coolant fluids and the backside of the first device 404.

As shown, the manifold 410 also comprises a third section of the first coolant channel 408 that couples the second opening 420 to the second section of the first coolant channel 408 formed within the first support feature 416. A portion 438 of the third section of the first coolant channel 408 may be the same or similar to the portion 436 of the second section of the first coolant channel 408. For example, the portion 438 of the third section of the first coolant channel 408 may be proximate to the backside of the second device 430 to facilitate thermal dissipation. In some embodiments, the backside of the second device 430 is directly exposed to coolant fluids flowing through the portion 438 of the third section of the first coolant channel 408 proximate to the backside of the second device 430. In some embodiments, there is a thin barrier between the portion 438 of the third section of the first coolant channel 408 and the backside of the second device 430 preventing direct contact between the coolant fluids and the backside of the second device 430.

In some embodiments, the manifold 310 comprises a first section of the second coolant channel 412 that couples the third opening 426 to a second section of the second coolant channel 412 formed within the second support feature 424. A portion of the second section of the second coolant channel 440 may be proximate to the backside of the first device 404 to facilitate thermal dissipation as described herein. The manifold 410 may also comprise a third section of the second coolant channel 412 that couples the fourth opening 428 to the second section of the second coolant channel 412 formed within the second support feature 424.

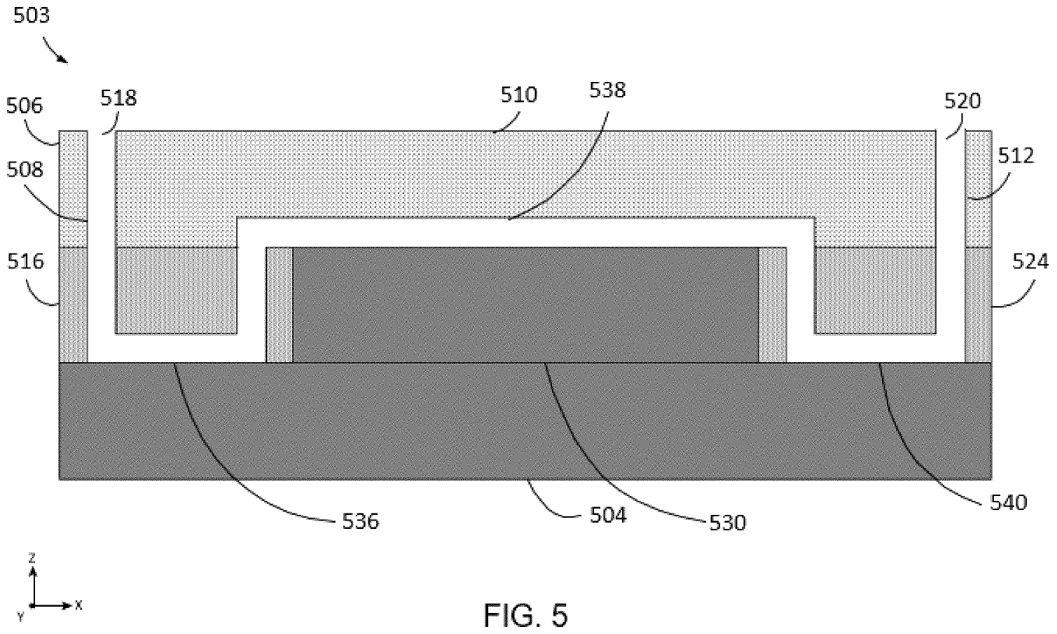

FIG. 5 is a schematic sectional view of at least a portion of an integrated cooling assembly 503 comprising a third coolant channel design. In some embodiments, FIG. 5 displays the same or a similar coolant channel design to the one described in FIG. 2. For example, the integrated cooling assembly 503 may comprise a cold plate 506, a first device 504, and a second device 530, where the cold plate 506 comprises a manifold 510, a first support feature 516, a second support feature 524, and a first coolant channel 508.

In some embodiments, the manifold 510 comprises a first opening 518 and a second opening 520 to allow coolant fluid to flow through the first coolant channel 508. In some embodiments, one or more portions of the first coolant channel 508 are proximate to one or more devices to facilitate thermal dissipation. For example, a first portion 536 of the first coolant channel 508 may be proximate to a first portion of the backside of the first device 504. In another example, a second portion 538 of the first coolant channel 508 may be proximate to a first portion of the backside of the second device 530. In another example, a third portion 540 of the first coolant channel 508 may be proximate to a second portion of the backside of the first device 504. In some embodiments, the backsides of the devices are directly exposed to coolant fluids flowing through the respective portions of the first coolant channel 508 proximate to said devices. In some embodiments, there is a thin barrier between the respective portions of the first coolant channel 508 and the backsides of the devices preventing direct contact between the coolant fluids and the backside of the devices. In some embodiments, a fourth portion 512 of the first coolant channel 508 may be proximate to a fourth portion of the first device 504.

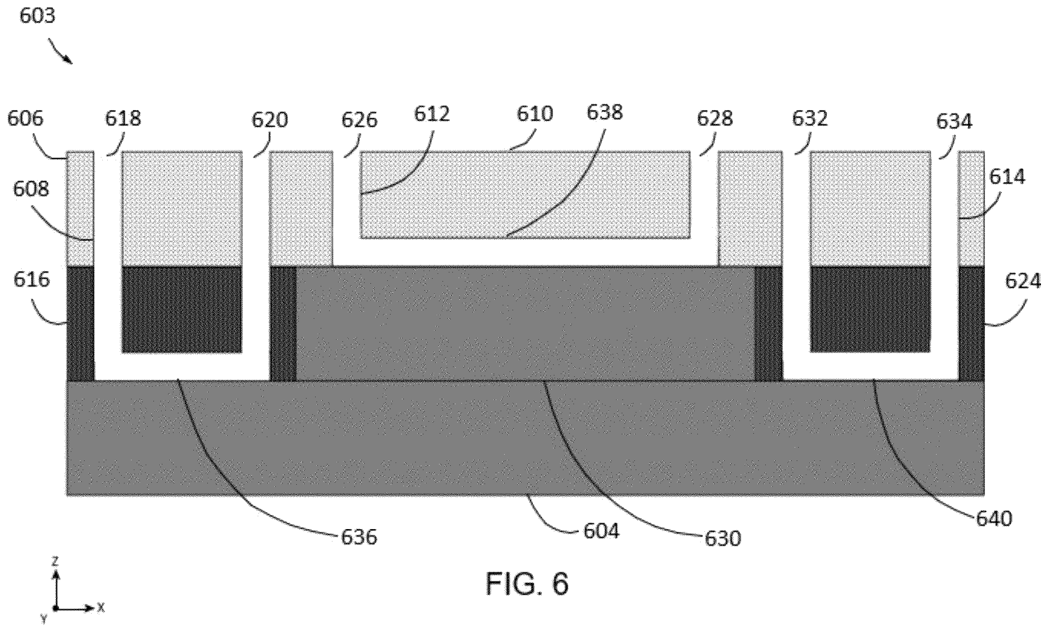

FIG. 6 is a schematic sectional view of at least a portion of an integrated cooling assembly 603 including a first device 604, a second device 630, and a cold plate 606. Here, the first device 604 and/or the second device 630 may be a die, a wafer, and/or a portion of a reconstituted wafer, and the second device 630 is bonded to the first device 604. For example, the second device 630 may be a reconstituted memory die bonded to the first device 604, which may be a logic wafer/die or a reconstituted logic wafer/die. The first device 604 and/or the second device 630 may include an active side that includes device components (e.g., transistors, resistors, capacitors, etc.) formed thereon or therein, and a non-active side (e.g., the device backside) opposite the active side.

In some embodiments, the cold plate 606 comprises a manifold 610, a first support feature 616, a second support feature 624, and/or one or more coolant channels. The first support feature 616 and/or the second support feature 624 may be formed during a reconstitution process. For example, one or more support features and the second device 630 are bonded to the first device 604 (which may be a wafer or a reconstituted wafer) and one or more spaces between the one or more support features and the second device 630 are filled using organic or inorganic dielectric material. A first portion of the dielectric material may correspond to the first support feature 616 and a second portion of the dielectric material may correspond to the second support feature 624. In some embodiments, coolant channels (e.g., the first coolant channel 608) are formed within the first support feature 616 and/or the second support feature 624 after the one or more spaces between the one or more support features and the second device 630 are filled using organic or inorganic dielectric material. In some embodiments, the second device 630 may be a reconstituted memory die and may be surrounded by a dielectric material during a reconstitution process. Although two support features are shown, the cold plate 606 may comprise more or fewer support features.

In some embodiments, the manifold 610 comprises a first opening 618, a second opening 620, a third opening 626, a fourth opening 628, a fifth opening 632, and a sixth opening 634. In some embodiments, the openings are in fluid communication with the inlet/outlet openings of a package cover through openings formed in a sealing material layer disposed therebetween. Although six openings are displayed, more or fewer openings may be used. As shown, the integrated cooling assembly 603 comprises a coolant channel design that is the same or similar to the first coolant channel design described at FIG. 3. For example, the cold plate 606 comprises a first coolant channel 608 with a portion 636 of the first coolant channel 608 proximate to the first device 604, a second coolant channel 612 with a portion 638 of the second coolant channel 612 proximate to the second device 630, and a third coolant channel 614 with a portion 640 of the third coolant channel 614 proximate to the first device 604.

In some embodiments, the portions of the coolant channels proximate to the devices provide thermal dissipation. For example, the backside of the first device 604 may be directly exposed to coolant fluids flowing through the portion 636 of the first coolant channel 608 proximate to the backside of the first device 604. In some embodiments, there is a thin barrier (e.g., a lower portion of the first support feature 616) between the portion of 636 the first coolant channel 608 and the backside of the first device 604 preventing direct contact between the coolant fluids and the backside of the first device 604. In another example, the backside of the second device 630 may be directly exposed to coolant fluids flowing through the portion 638 of the second coolant channel 612 proximate to the backside of the second device 630. In some embodiments, there is a thin barrier (e.g., a lower portion of the cold plate 606) between the portion of 638 the second coolant channel 612 and the backside of the second device 630 preventing direct contact between the coolant fluids and the backside of the second device 630. In another example, an additional portion of the backside of the first device 604 may be directly exposed to coolant fluids flowing through the portion 640 of the third coolant channel 614 proximate to the additional portion of the backside of the first device 604. In some embodiments, there is a thin barrier (e.g., a lower portion of the second support feature 624) between the portion of 640 the third coolant channel 614 and the additional portion of the backside of the first device 604 preventing direct contact between the coolant fluids and the additional portion of backside of the first device 604.

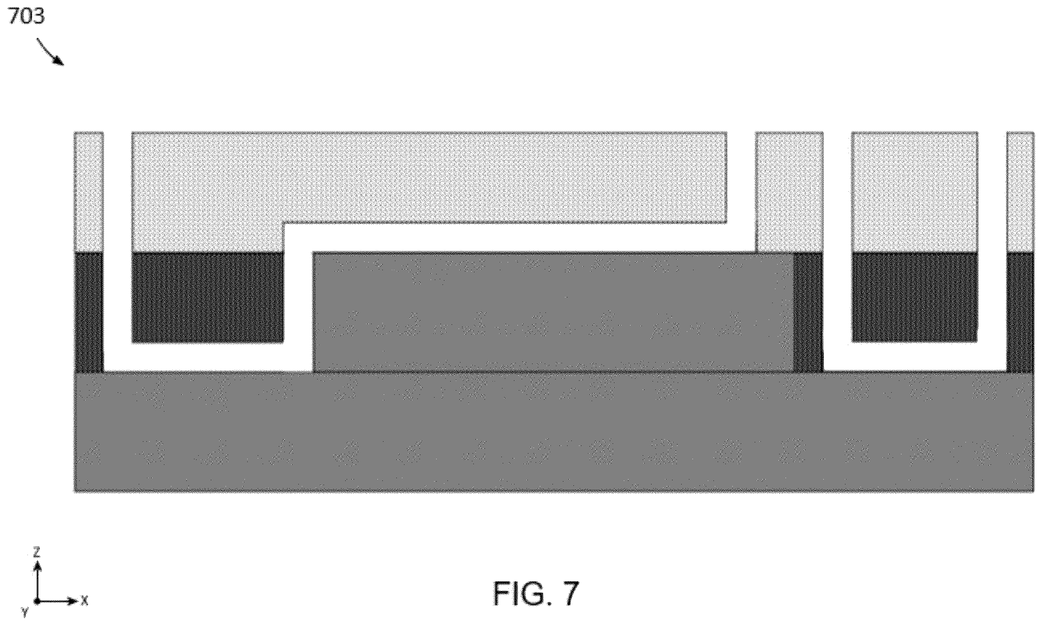

Although FIG. 6 displays the at least a portion of the integrated cooling assembly 603 with support features corresponding to one or more portions of a reconstituted wafer and the first coolant channel design, other coolant channel designs may be incorporated. For example, FIG. 7 is a schematic sectional view of at least a portion of an integrated cooling assembly 703 with support features corresponding to one or more portions of a reconstituted wafer and a coolant channel design the same or similar to the second coolant channel design described at FIG. 4. In some embodiments, the support features of FIG. 7 may be formed during a reconstitution process. For example, one or more support features and a first device may be bonded to a second device (which may be a wafer or a reconstituted wafer) and one or more spaces between the one or more support features and the first device are filled using organic or inorganic dielectric material. In some embodiments, one or more portions of one or more coolant channels (e.g., the two coolant channels displayed in FIG. 7) are formed within the one or more support features after the one or more spaces between the one or more support features and the first device are filled using organic or inorganic dielectric material.

In some embodiments, the portions of the coolant channels proximate to the devices provide thermal dissipation. For example, a backside of a first device may be directly exposed to coolant fluids flowing through a portion of a coolant channel (e.g., first or second coolant channel displayed in FIG. 7) proximate to the backside of the first device. In some embodiments, there is a thin barrier between the portion of the coolant channel and the backside of the first device preventing direct contact between the coolant fluids and the backside of the first device. In another example, a backside of a first device and a backside of a second device may be directly exposed to coolant fluids flowing through portions of a coolant channel proximate to the backside of the first device and the backside of the second device.

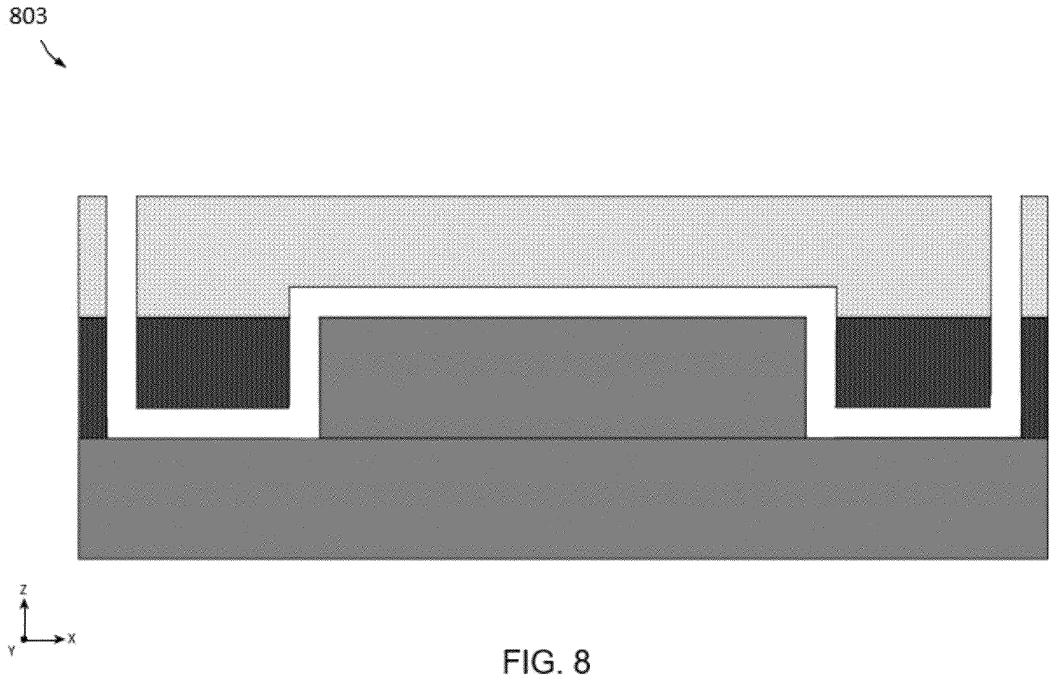

In another example, FIG. 8 is a schematic sectional view of at least a portion of an integrated cooling assembly 803 with support features corresponding to one or more portions of a reconstituted wafer and a coolant channel design the same or similar to the third coolant channel design described at FIG. 5. In some embodiments, the support features of FIG. 8 may be formed during a reconstitution process. For example, one or more support features and a first device may be bonded to a second device (which may be a wafer or a reconstituted wafer) and one or more spaces between the one or more support features and the first device are filled using organic or inorganic dielectric material. In some embodiments, one or more portions of a coolant channel (e.g., the coolant channel displayed in FIG. 8) are formed within the one or more support features after the one or more spaces between the one or more support features and the first device are filled using organic or inorganic dielectric material.

In some embodiments, the portions of the coolant channels proximate to the devices provide thermal dissipation. For example, a backside of a first device may be directly exposed to coolant fluids flowing through a portion of a coolant channel (e.g., coolant channel displayed in FIG. 7) proximate to the backside of the first device. In some embodiments, there is a thin barrier between the portion of the coolant channel and the backside of the first device preventing direct contact between the coolant fluids and the backside of the first device. In another example, a backside of a first device and a backside of a second device may be directly exposed to coolant fluids flowing through portions of the coolant channel proximate to the backside of the first device and the backside of the second device.

In some embodiments, any of the integrated cooling assemblies described herein may use any of the coolant channel designs described herein and/or any portions of the coolant channel designs described herein.

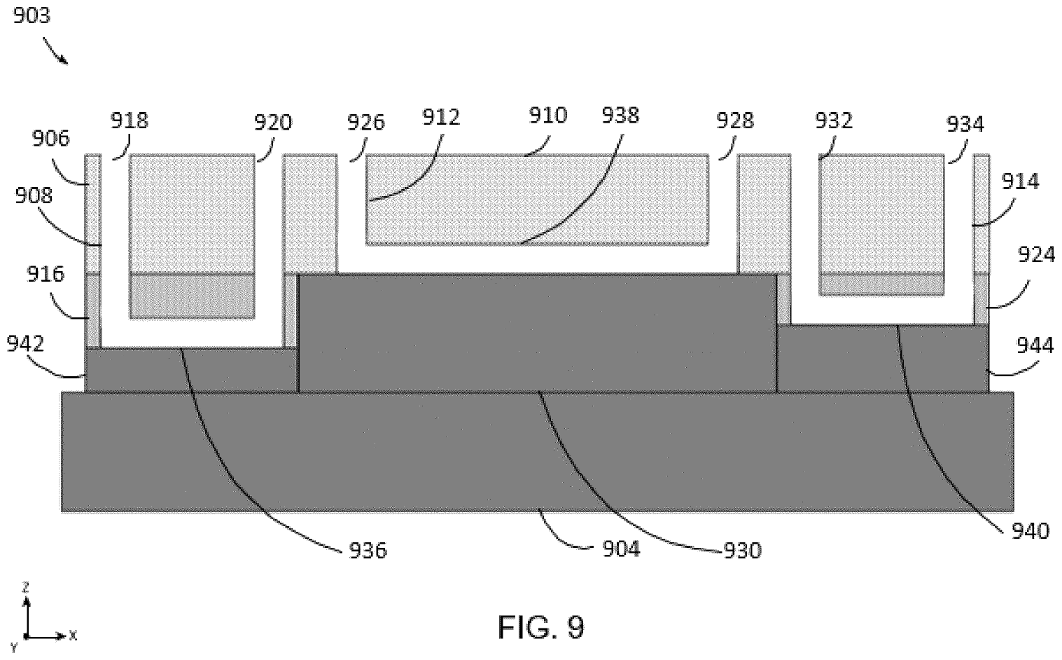

FIG. 9 is a schematic sectional view of at least a portion of the integrated cooling assembly 903 comprising a cold plate 906, a first device 904, a second device 942, a third device 930, and a fourth device 944. Here, the second device 942, the third device 930, and the fourth device 944 are bonded to the first device 904, and the cold plate 906 is bonded to the second device 942, the third device 930, the fourth device 944, and/or the first device 904. In some embodiments, one or more of the second device 942, the third device 930, and/or the fourth device 944 may be active die(s) or dummy dies(s). In some embodiments, the second device 942, the third device 930, and/or the fourth device 944 are directly bonded to the first device 904 (which may be a device wafer, an interposer, or a reconstituted wafer). In some embodiments, the second device 942, the third device 930, and/or the fourth device 944 may be reconstituted on the first device 904. For example, the second device 942, the third device 930, and/or the fourth device 944 may be bonded to first device 904 and then one or more gaps between the second device 942, the third device 930, and/or the fourth device 944 may be filled with dielectric material. Therefore, the second device 942, the third device 930, and the fourth device 944 bonded to the first device 904 are stacked to define different stacked heights, according to the respective thickness of each device. As shown, the stacked height of the second device 942 and the first device 904 is different from the stacked height of the third device 930 and the first device 904. Further, the stacked height of fourth device 944 and the first device 904 is different from the stacked height of the third device 930 and the first device 904 and is different from the stacked height of second device 942 and the first device 904. As described above, the devices may include active sides that includes device components (e.g., transistors, resistors, capacitors, etc.) formed thereon or therein, and non-active sides, the device backsides, opposite the active sides. In some embodiments, one or more devices have different thicknesses. Thicknesses of the one or more devices are measured in the Z-axis direction between top and bottom surfaces of the devices. For example, the second device 942 may have a first thickness, the third device 930 may have as a second thickness, and the fourth device 944 may have a third thickness. In some embodiments, each thickness is different. In some embodiments, one or more thicknesses may be the same or similar.

In some embodiments, the cold plate 906 comprises a manifold 910, a first support feature 916, a second support feature 924, a first coolant channel 908, a second coolant channel 912, and a third coolant channel 914. The manifold 910 may comprise a first opening 918, a second opening 920, a third opening 926, a fourth opening 928, a fifth opening 932, and a sixth opening 934. Although six openings are displayed, more or fewer openings may be used. In some embodiments, one or more openings allow coolant fluid to flow through one or more coolant channels. For example, the first opening 918 and the second opening 920 may allow coolant fluid to flow into and out of the first coolant channel 908. In some embodiments, each of the coolant channels receives coolant fluid from a single coolant source, then transfers the received coolant fluid back to the coolant source. In some embodiments, one or more coolant channels receive coolant fluid from different coolant sources. For example, the first coolant channel 908 may receive coolant fluid from a first coolant source, and the second coolant channel 912 and the third coolant channel 914 may receive coolant fluid from a second coolant source. In some embodiments, support features 924 are formed from the encapsulation or the reconstitution dielectric deposited after the devices 942, 930 and 944 are bonded to first device 904. The encapsulation or the reconstitution dielectric can be present in the gaps between the second device 942, the third device 930, and/or the fourth device 944.

In some embodiments, the manifold 910, the first support feature 916, and/or the second support feature 924 each comprise one or more sections of a coolant channel. As shown, the manifold 910 comprises a first section of the first coolant channel 908 that couples the first opening 918 to a second section of the first coolant channel 908 formed within the first support feature 916. The second section of the first coolant channel 908 couples the first section of the first coolant channel 908 to a third section of the first coolant channel 908 formed within the manifold 910. A portion 936 of the second section of the first coolant channel 908 may be proximate to the backside of the second device 942 to facilitate thermal dissipation. The manifold 910 may also comprises a third section of the first coolant channel 908 that couples the second opening 920 to the second section of the first coolant channel 908 formed within the first support feature 916.

As shown, the manifold 910 comprises the second coolant channel 912 coupled to the third opening 926 and the fourth opening 928. A portion 938 of the second coolant channel 912 may be proximate to the backside of the third device 930 to facilitate thermal dissipation. In some embodiments, the manifold 910 also comprises a first section of the third coolant channel 914 that couples the fifth opening 932 to a second section of the third coolant channel 914 formed within the second support feature 924. The second section of the third coolant channel 914 couples the first section of the third coolant channel 914 to a third section of the third coolant channel 914 formed within the manifold 910. A portion 940 of the second section of the third coolant channel 914 may be proximate to the backside of the fourth device 944 to facilitate thermal dissipation. The manifold 910 may also comprises a third section of the third coolant channel 914 that couples the sixth opening 934 to the second section of the third coolant channel 914 formed within the second support feature 924. Although three coolant channels are shown, any number of coolant channels may be used.

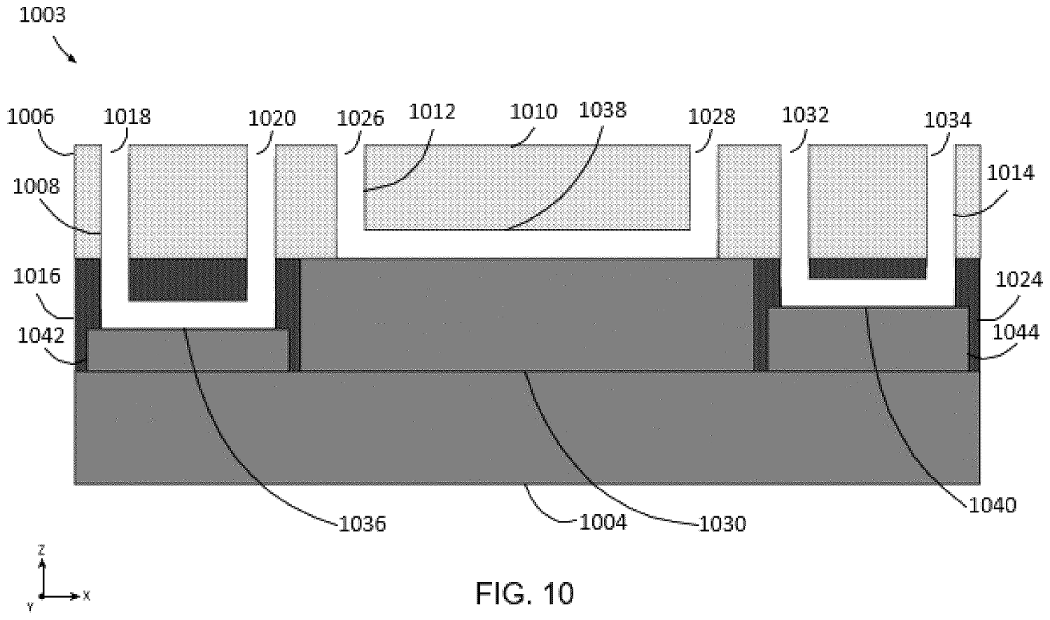

FIG. 10 is a schematic sectional view of at least a portion of an integrated cooling assembly 1003 including a first device 1004, a second device 1042, a third device 1030, a fourth device 1044, and a cold plate 1006. Here, the first device 1004 may be a die, a wafer, and/or a portion of a reconstituted wafer, and the second device 1042, the third device 1030, and the fourth device 1044 are bonded to the first device 1004. For example, the second device 1042, the third device 1030, and/or the fourth device 1044 may be reconstituted memory dies bonded to the first device 1004, which is a reconstituted logic die. In some embodiments, one or more of the second device 1042, the third device 1030, and/or the fourth device 1044 can be active die(s) or dummy dies(s). In some embodiments, the second device 1042, the third device 1030, and/or the fourth device 1044 are directly bonded to first device 1004 which may be a device wafer, an interposer, or a reconstituted wafer. In some embodiments, the second device 1042, the third device 1030, and/or the fourth device 1044 may be reconstituted on the first device 1004. For example, the second device 1042, the third device 1030, and/or the fourth device 1044 may be bonded to first device 1004 and then one or more gaps between the second device 1042, the third device 1030, and/or the fourth device 1044 may be filled with dielectric material. In some embodiments, the dielectric material filled between the gaps between the second device 1042, the third device 1030, and/or the fourth device 1044 comprise organic material (e.g. polymer, epoxy, resin, etc.) or inorganic material (e.g. silicon oxide, silicon nitride). In some embodiments, one or more such gaps are filled with one or more layers of dielectric materials. In some embodiments, one or more of the first device 1004, second device 1042, the third device 1030, and/or the fourth device 1044 are memory die(s), logic die(s), or a dummy die(s). As described above, the devices may include active sides that includes device components (e.g., transistors, resistors, capacitors, etc.) formed thereon or therein, and non-active sides opposite the active sides. In some embodiments, one or more devices have different thicknesses. Thicknesses of the one or more devices are measured in the Z-axis direction between top and bottom surfaces of the devices. For example, the second device 1042 may have a first thickness, the third device 1030 may have as a second thickness, and the fourth device 1044 may have a third thickness. In some embodiments, each thickness is different. In some embodiments, one or more thicknesses may be the same or similar.

In some embodiments, the cold plate 1006 comprises a manifold 1010, a first support feature 1016, a second support feature 1024, and/or one or more coolant channels. The first support feature 1016 and/or the second support feature 1024 may be one or more portions of a molding deposited during a reconstitution process. For example, the second device 1042, the third device 1030, and/or the fourth device 1044 may be reconstituted memory dies and may be surrounded by molding during a reconstitution process. In some embodiments, the molding is made of a dielectric material. A first portion of the molding may correspond to the first support feature 1016 and a second portion of the molding may correspond to the second support feature 1024. Although two support features are shown, the cold plate 1006 may comprise more or fewer support features.

In some embodiments, the manifold 1010 comprises a first opening 1018, a second opening 1020, a third opening 1026, a fourth opening 1028, a fifth opening 1032, and a sixth opening 1034. In some embodiments, the openings are in fluid communication with the inlet/outlet openings of a package cover through openings formed in a sealing material layer disposed therebetween. Although six openings are displayed, more or fewer openings may be used. As shown, the integrated cooling assembly 1003 comprises a coolant channel design that is the same or similar to the coolant channel design described at FIG. 9. For example, the cold plate 1006 comprises a first coolant channel 1008 with a portion 1036 of the first coolant channel 1008 proximate to the second device 1042, a second coolant channel 1012 with a portion 1038 of the second coolant channel 1012 proximate to the third device 1030, and a third coolant channel 1014 with a portion 1040 of the third coolant channel 1014 proximate to the fourth device 1044. Although three coolant channels are shown, any number of coolant channels may be used.

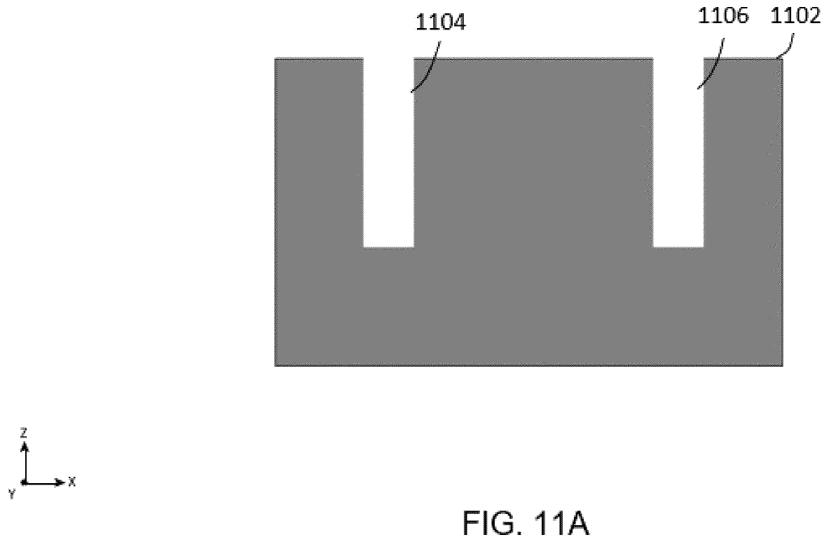

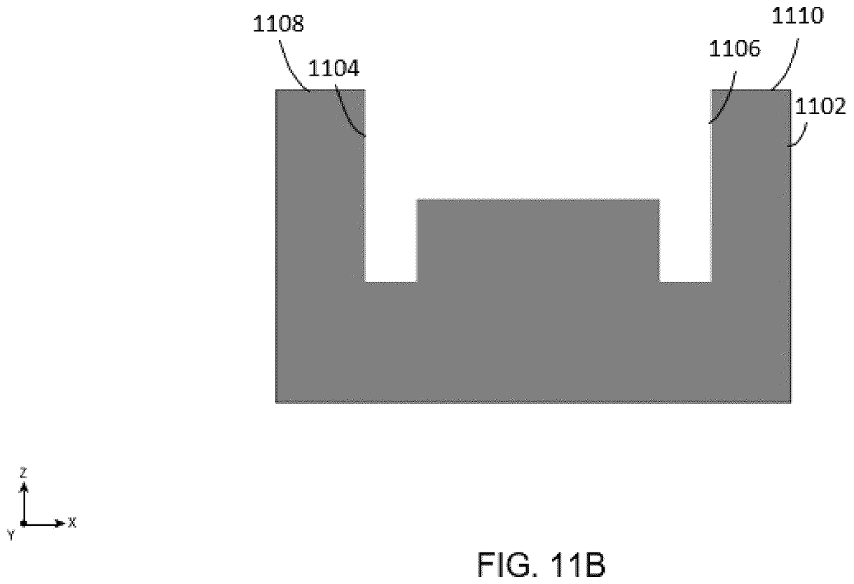

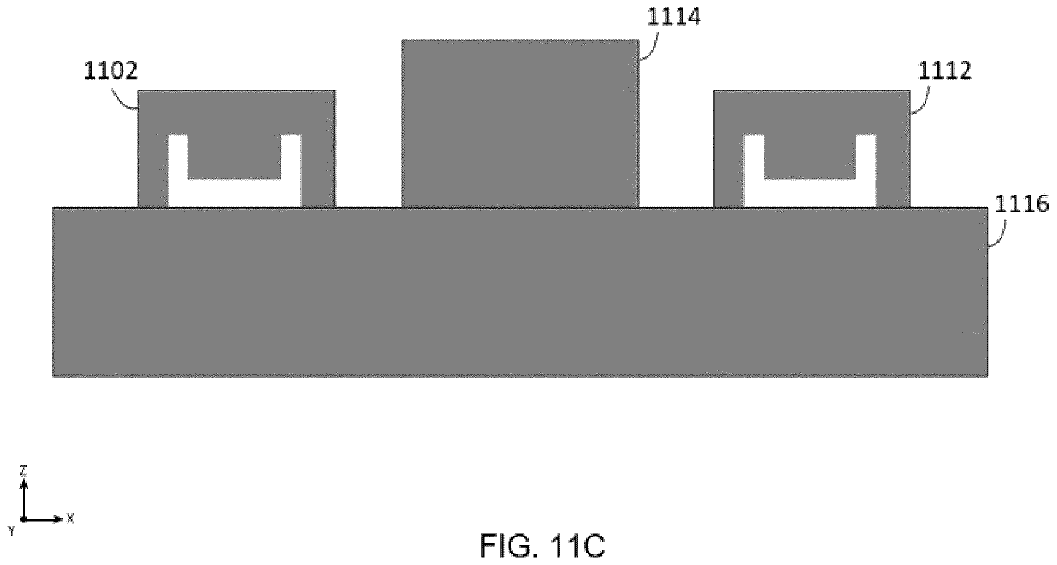

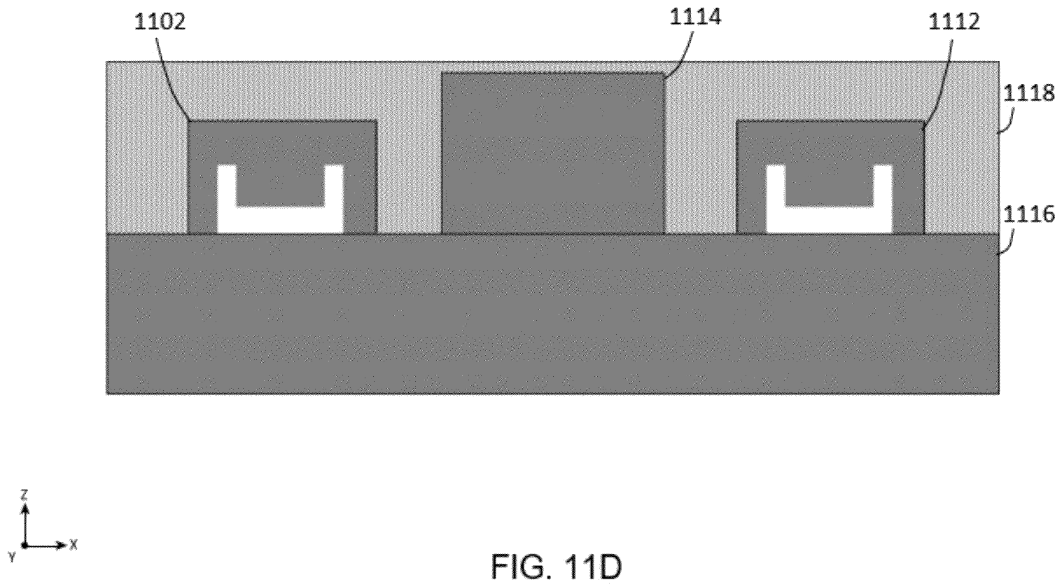

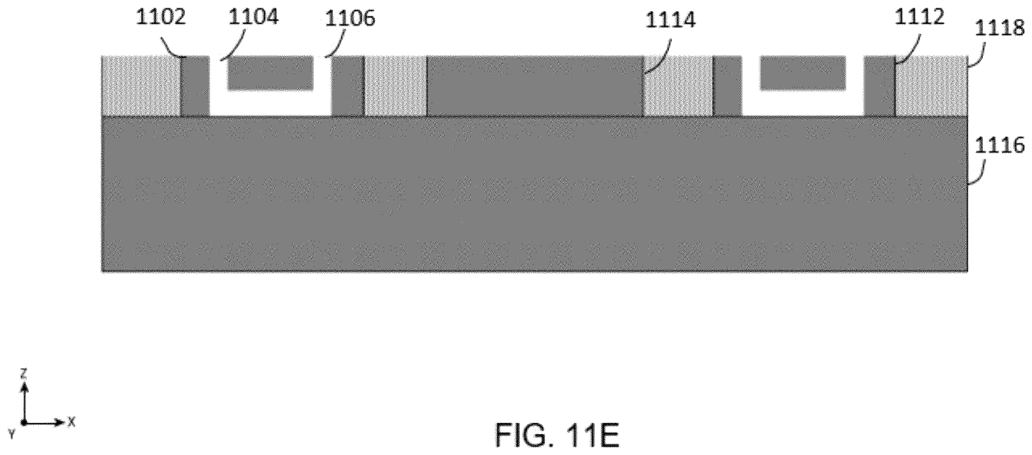

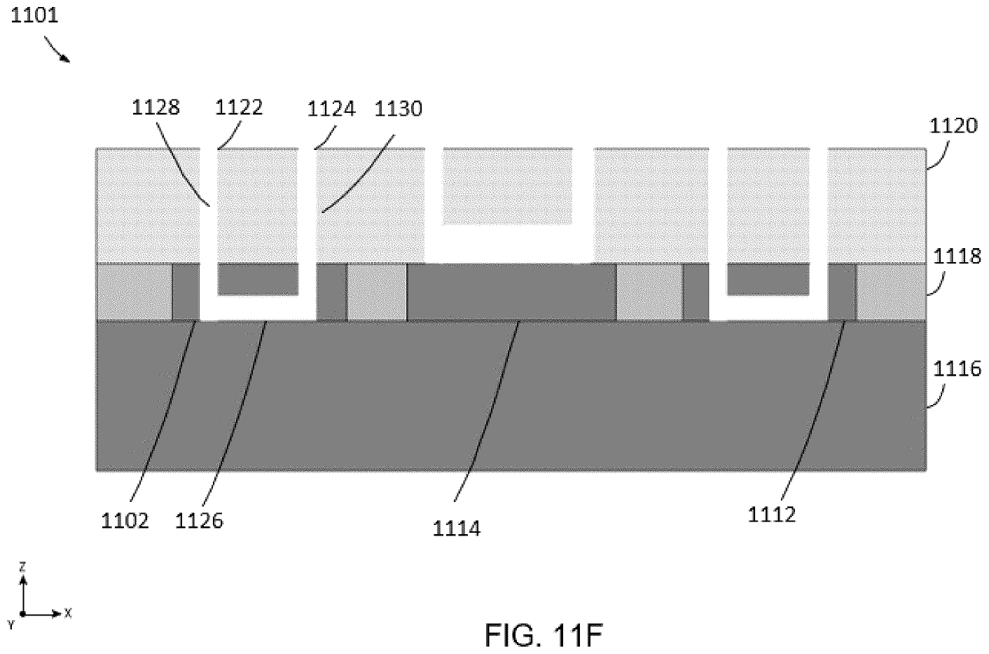

FIGS. 11A-11F are schematic partial sectional side views showing a process for manufacturing at least a portion of an integrated cooling assembly, in accordance with some embodiments of the disclosure. FIG. 11A displays a first via 1104 and a second via 1106 formed in a first support feature 1102. In some embodiments, the first support feature 1102 is a dummy die. For example, the first support feature 1102 may comprise a non-operational die, filler (encapsulant) material, organic material, inorganic material, a portion of a reconstituted wafer, a blank carrier (e.g. silicon, ceramic, glass, etc.), and/or the like.

In some embodiments, the first via 1104 and/or the second via 1106 are formed using one or more etching processes (e.g., dry etching, wet etching, laser etching, etc.), patterning processes, and/or similar such processes. For example, one or more patterned mask layers may be deposited on the first support feature 1102 while an etchant is used to form the first via 1104 and/or the second via 1106. In some embodiments, an anisotropic etch process is used, which uses inherently differing etch rates for the silicon material, which is exposed to an anisotropic etchant when the patterned mask layer is formed. The etching process is controlled to where the etch rates of the exposed material have a ratio between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN4OH), hydrazine (N2H4), or tetra methyl ammonium hydroxide (TMAH). The actual differing etch rates depend on the concentration of the etchant in the aqueous solution, the temperature of the aqueous solution, and a concentration of the dopant in the substrates (if any). Typically, the mask layer is formed of a material that is selective to anisotropic etch compared to the underlying monocrystalline silicon substrate. Examples of suitable mask materials include silicon oxide (SixOy) or silicon nitride (SixNy). In some embodiments, the mask layer has a thickness of about 100 nm or less, such as about 50 nm or less, or about 30 nm or less. The mask layer may be patterned using any suitable combination of lithography and material etching patterning methods.

FIG. 11B displays the first support feature 1102 after a portion of a coolant channel is formed at the base of support feature 1102. Although only one coolant channel is depicted, more such channels of different shapes and sizes can be formed. In some embodiments, the portion of the coolant channel is formed using one or more etching processes (e.g., dry etching, wet etching, laser etching, etc.), patterning processes, and/or similar such processes as described herein. In some embodiments, the same process(es) that formed the first via 1104 and/or the second via 1106 is used to form the portion of the coolant channel. In some embodiments, a first surface 1108 and/or a second surface 1110 of the first support feature 1102 is prepared for bonding before or after the portion of the coolant channel is formed.

FIG. 11C displays the first support feature 1102 bonded to a first component 1116. The first support feature 1102 is flipped (compared to FIG. 11B) before bonding such that etched surfaces of the first support feature 1102 face the first component 1116 when bonded together. In some embodiments, the first component 1116 is a die, a wafer, and/or a portion of a reconstituted wafer. Here, the first support feature 1102, a second support feature 1112, and a first device 1114 are all bonded to the first component 1116. In some embodiments, one or more of the first support feature 1102, the second support feature 1112, and/or the first device 1114 are bonded to the first component 1116 using a direct bonding process or a hybrid bonding process. In some embodiments, the second support feature 1112 is generated using the same or similar processes used to generate the first support feature 1102 described herein.

FIG. 11D displays the first support feature 1102, the second support feature 1112, and the first device 1114 after undergoing a reconstitution process.

In some embodiments, the first support feature 1102, the second support feature 1112, and the first device 1114 undergo the reconstitution process after being bonded to the first component 1116. In some embodiments, a dielectric layer 1118 is deposited on the first support feature 1102, the second support feature 1112, the first device 1114, and/or the first component 1116 during the reconstitution process. In some embodiments, the dielectric layer 1118 comprise of one or more layers of organic (e.g., epoxy, resin, polymer, mold compound, etc.) or inorganic dielectric material (e.g., silicon oxide, silicon nitride, silicon oxynitride, silicon carbonitride, etc.).

FIG. 11E displays the first support feature 1102, the second support feature 1112, and the first device 1114 after undergoing a thinning process. In some embodiments, the first support feature 1102, the second support feature 1112, the first device 1114, and/or the dielectric layer 1118 are thinned to expose one or more vias of the support features. For example, the first support feature 1102, the second support feature 1112, the first device 1114, and the dielectric layer 1118 may be thinned to expose the first via 1104 and the second via 1106 of the first support feature 1102. In some embodiments, the thinning process comprises one or more backgrinding, etching, and polishing operations (e.g., CMP) that remove material. The thinning process may include using a combination of grinding and etching processes to reduce the thickness (in the Z-direction).

FIG. 11F displays a manifold 1120 bonded to the first support feature 1102, the second support feature 1112, the first device 1114, and/or the dielectric layer 1118. In some embodiments, the manifold 1120 can be bonded using a direct bonding process or may be bonding using sealing material (e.g., as shown in FIG. 1C). In some embodiments, the manifold 1120 comprises one or more openings to allow coolant fluid to flow into and out of one or more sections of a coolant channel. For example, the manifold 1120 may comprise a first opening 1122 and a second opening 1124 allowing coolant fluid to flow into and out of a first coolant channel 1126. In some embodiments, the manifold 1120 comprises one or more coolant channels and/or one or more sections of a coolant channel. In some embodiments, one or more coolant channels and/or one or more sections of the coolant channels are formed prior to the manifold 1120 being bonded to the first support feature 1102, the second support feature 1112, the first device 1114, and/or the dielectric layer 1118. In some embodiments, one or more sections of a coolant channel are formed within the manifold 1120 to align with sections of said coolant channel formed within the first support feature 1102, the second support feature 1112, and/or the dielectric layer 1118. For example, the manifold 1120 may comprise a first section 1128 of the first coolant channel 1126 and a third section 1130 of the first coolant channel 1126. The first section 1128 of the first coolant channel 1126 and the third section 1130 of the first coolant channel 1126 may be formed within the manifold 1120 to couple with a second section of the first coolant channel 1126 formed within the first support feature 1102. In some embodiments, the one or more openings, the one or more coolant channels, and/or the one or more sections of a coolant channel are formed using one or more etching processes (e.g., dry etching, wet etching, laser etching, etc.), patterning processes, and/or similar such processes.

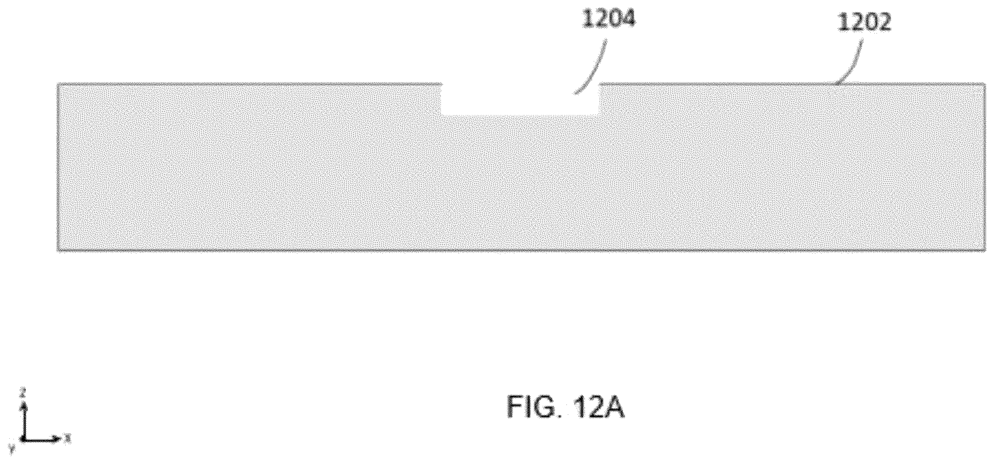

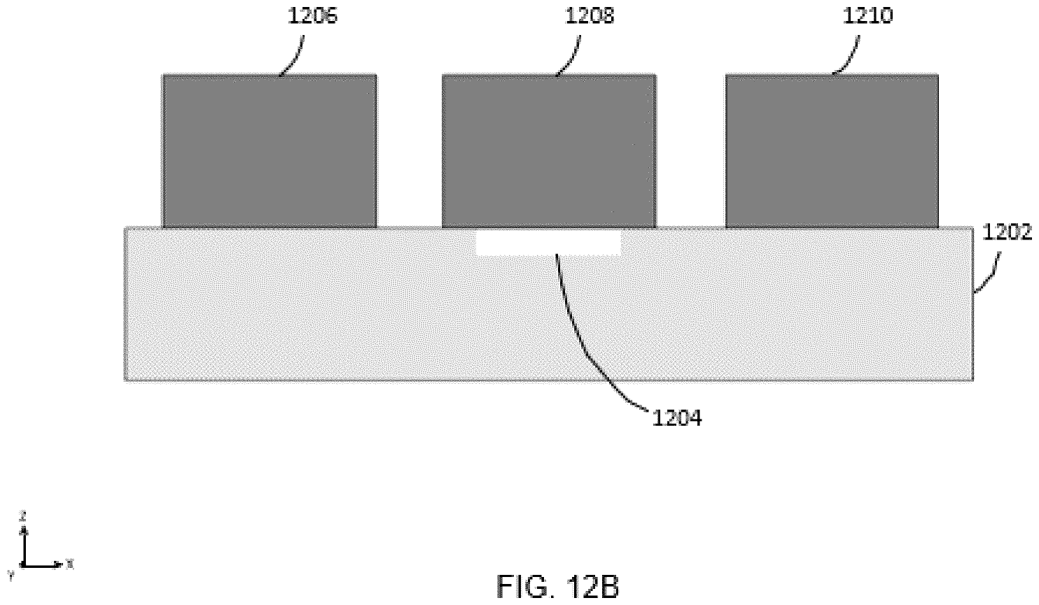

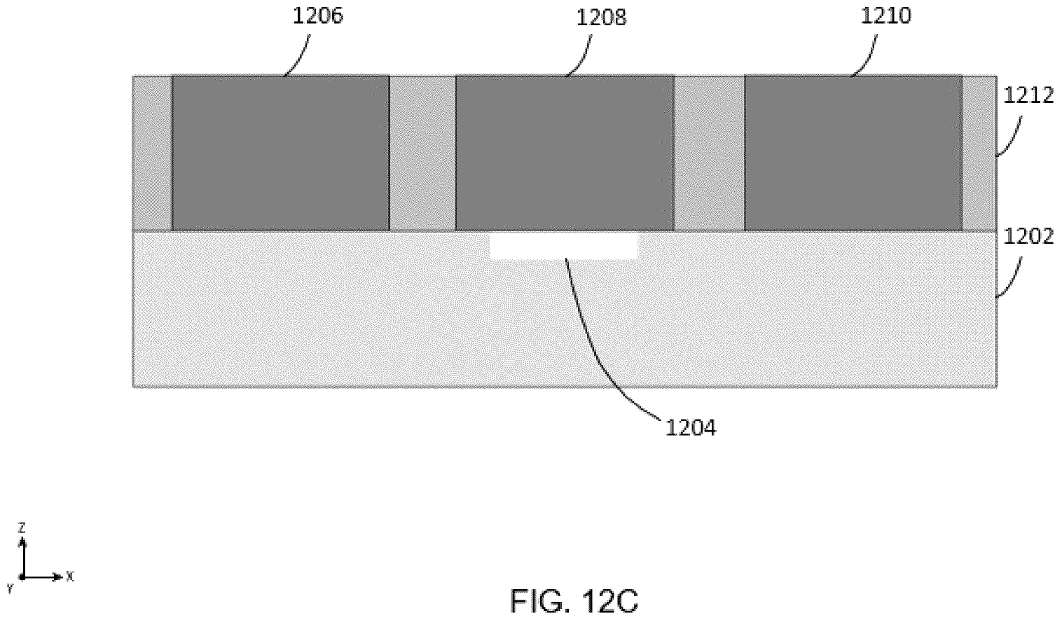

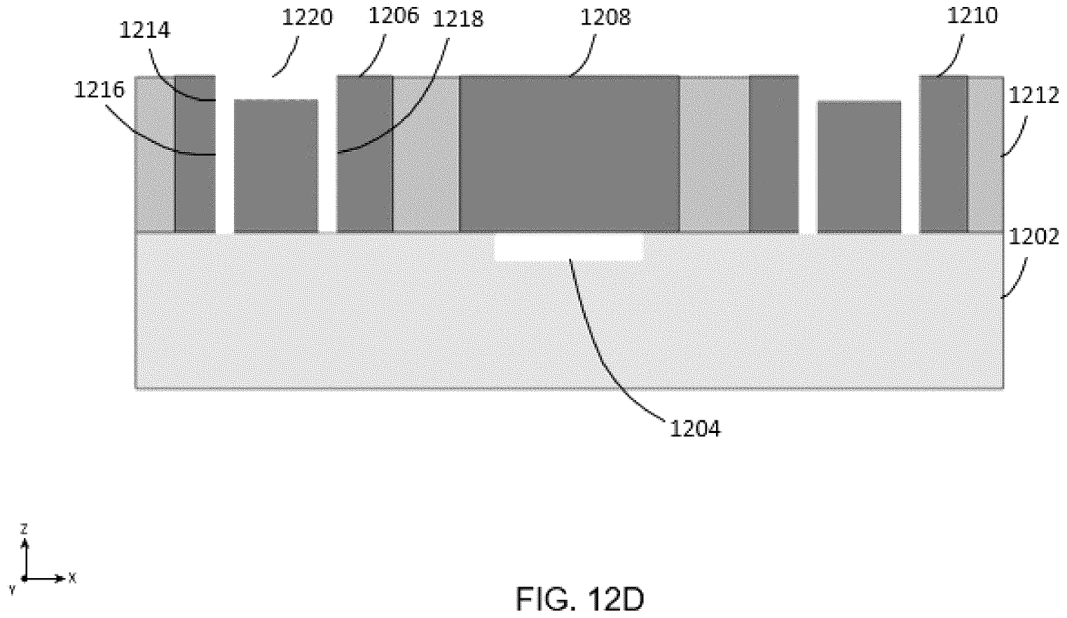

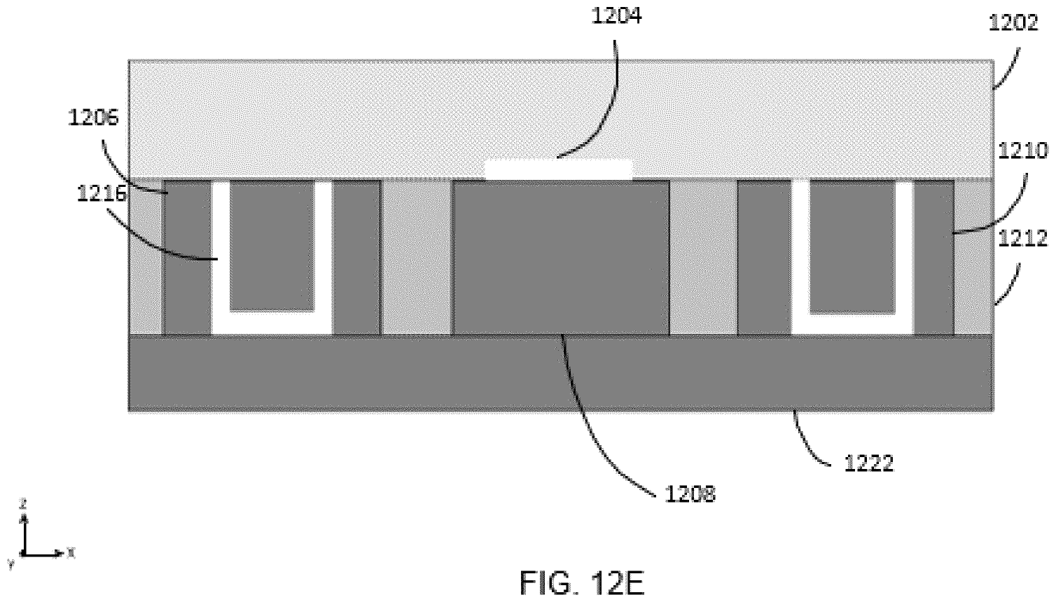

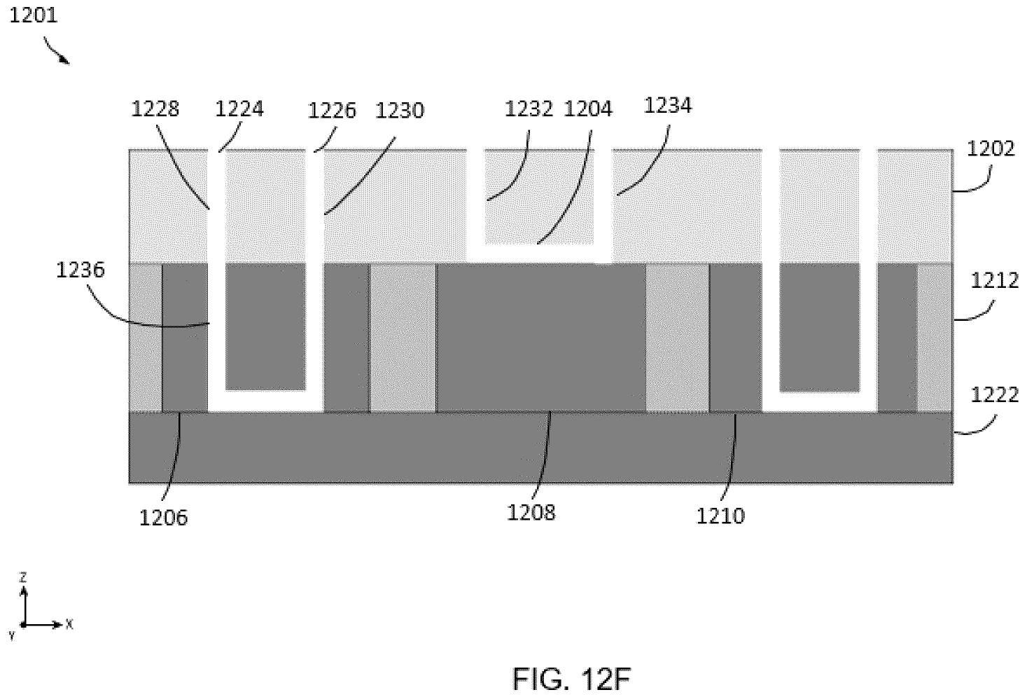

FIGS. 12A-12F are schematic partial sectional side views showing a process for manufacturing at least a portion of an integrated cooling assembly 1201, in accordance with some embodiments of the disclosure. FIG. 12A displays a portion 1204 of a coolant channel formed in a carrier wafer 1202. In some embodiments, the portion 1204 of the coolant channel is formed using one or more etching processes (e.g., dry etching, wet etching, laser etching, etc.), patterning processes, and/or similar such processes.

FIG. 12B displays a first support feature 1206, a second support feature 1210, and a first device 1208 bonded to the carrier wafer 1202. In some embodiments, the first support feature 1206 and/or the second support feature 1210 is a dummy die. For example, the first support feature 1206 and/or the second support feature 1210 may comprise a non-operational die, filler (encapsulant) material, organic material, inorganic material, a portion of a reconstituted wafer, a carrier (e.g., a carrier comprising silicon, ceramic, glass, etc.), and/or the like. In some embodiments, the first device 1208 comprises bonding pads (e.g., direct bond interconnect (DBI®) bonding pads) on the surface opposite the surface bonded to the carrier wafer 1202.

FIG. 12C displays the first support feature 1206, the second support feature 1210, and the first device 1208 after undergoing a reconstitution process. In some embodiments, a dielectric layer 1212 is deposited on the first support feature 1206, the second support feature 1210, the first device 1208, and/or the carrier wafer 1202 during the reconstitution process. In some embodiments, a grinding and/or etching process is used to remove a portion of the dielectric layer 1212 and expose the surface of the first device 1208 that is opposite the carrier wafer 1204. The first support feature 1206, the second support feature 1210, the first device 1208, and/or the dielectric layer 1212 may then be polished (e.g., using a chemical mechanical polishing (CMP) process) to a desired smoothness to prepare the first support feature 1206, the second support feature 1210, the first device 1208, and/or the dielectric layer 1212 for bonding.

In some embodiments, the first support feature 1206, the second support feature 1210, and/or the first device 1208 undergo one or more thinning processes. In some embodiments, the first support feature 1206, the second support feature 1210, and/or the first device 1208 are temporarily bonded to the carrier wafer 1202 before the thinning process, and the carrier wafer 1202 provides support for the thinning operation and/or for substrate handling during one or more of the subsequent manufacturing operations described herein. The first support feature 1206, the second support feature 1210, and/or the first device 1208 may be thinned to within 150 um or less of their final thickness.

FIG. 12D displays one or more segments of one or more coolant channels formed in the first support feature 1206 and the second support feature 1210. In some embodiments, the one or more segments of the one or more coolant channels are formed using one or more etching processes (e.g., dry etching, wet etching, laser etching, etc.), patterning processes, and/or similar such processes as described herein. In some embodiments, one or more segments of the one or more coolant channels are formed using multiple steps. For example, a first segment 1214 of a coolant channel may be formed in the first support feature 1206 by first forming a first via 1216 and a second via 1218 in the first support feature 1206. After the first via 1216 and the second via 1218 are formed, a portion 1220 of the first support feature may be etched away to form a portion of the first segment 1214 of the coolant channel.

FIG. 12E displays the first support feature 1206, the second support feature 1210, the first device 1208, and the dielectric layer 1212 bonded to a first component 1222. In some embodiments, the first component 1222 is a die, a wafer, or a reconstituted wafer. In some embodiments, the first support feature 1206, the second support feature 1210, the first device 1208, the dielectric layer 1212, and the carrier wafer 1202 are flipped (compared to FIG. 12D), such that etched surfaces face the first component 1222 when bonded together. In some embodiments, the first device 1208 and/or the first component 1222 are logic or memory die(s).

FIG. 12F displays one or more segments of one or more coolant channels formed in the carrier wafer 1202. In some embodiments, the one or more segments of the one or more coolant channels are formed using one or more etching processes (e.g., dry etching, wet etching, laser etching, etc.), patterning processes, and/or similar such processes as described herein. In some embodiments, one or more openings are formed in the carrier wafer 1202 to allow coolant fluid to flow into and out of one or more sections of a coolant channel. For example, the carrier wafer 1202 may comprise a first opening 1224 and a second opening 1226 allowing coolant fluid to flow into and out of a first coolant channel 1236. In some embodiments, the carrier wafer 1202 comprises one or more coolant channels and/or one or more sections of a coolant channel. In some embodiments, one or more sections of a coolant channel are formed within the carrier wafer 1202 to align with sections of said coolant channel formed within the first support feature 1206, the second support feature 1210, the dielectric layer 1212, and/or the carrier wafer 1202. For example, the carrier wafer 1202 may comprise a first section 1228 of the first coolant channel 1236 and a third section 1230 of the first coolant channel 1236. The first section 1228 of the first coolant channel 1236 and the third section 1230 of the first coolant channel 1236 may be formed within the carrier wafer 1202 to couple with a second section of the first coolant channel 1236 formed within the first support feature 1206. In another example, the carrier wafer 1202 may comprise a third via 1232 and a fourth via 1234. The third via 1232 and the fourth via 1234 may be formed within the carrier wafer 1202 to couple with the portion 1204 of the second coolant channel previously formed within the carrier wafer 1202.

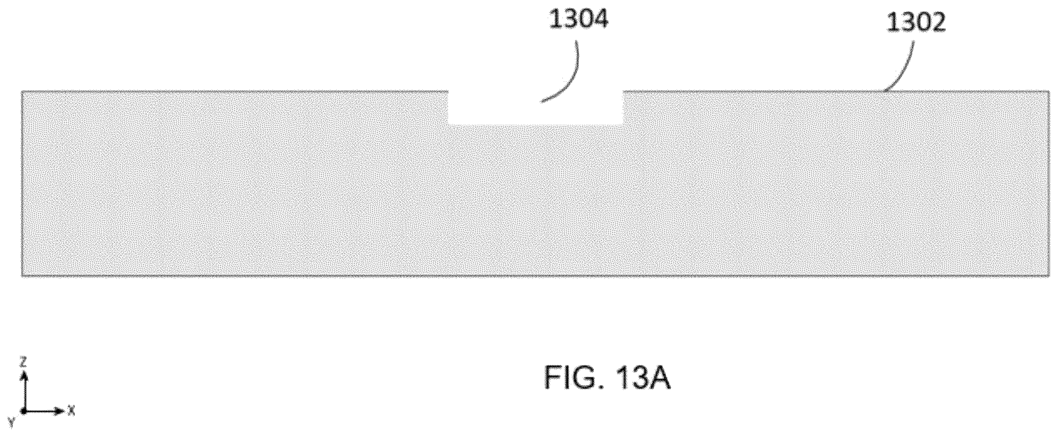

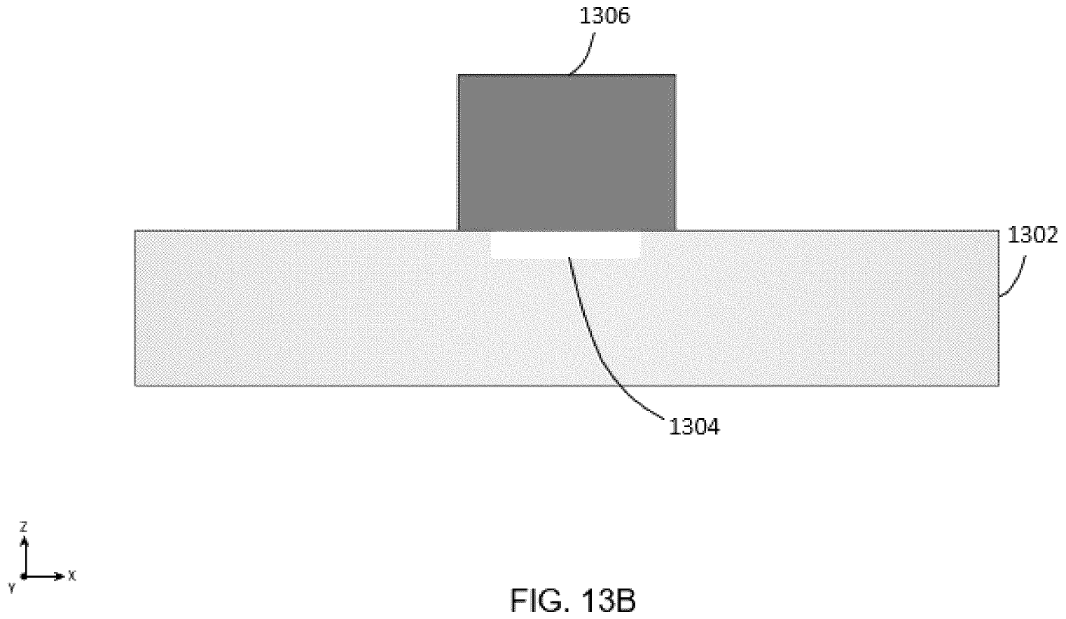

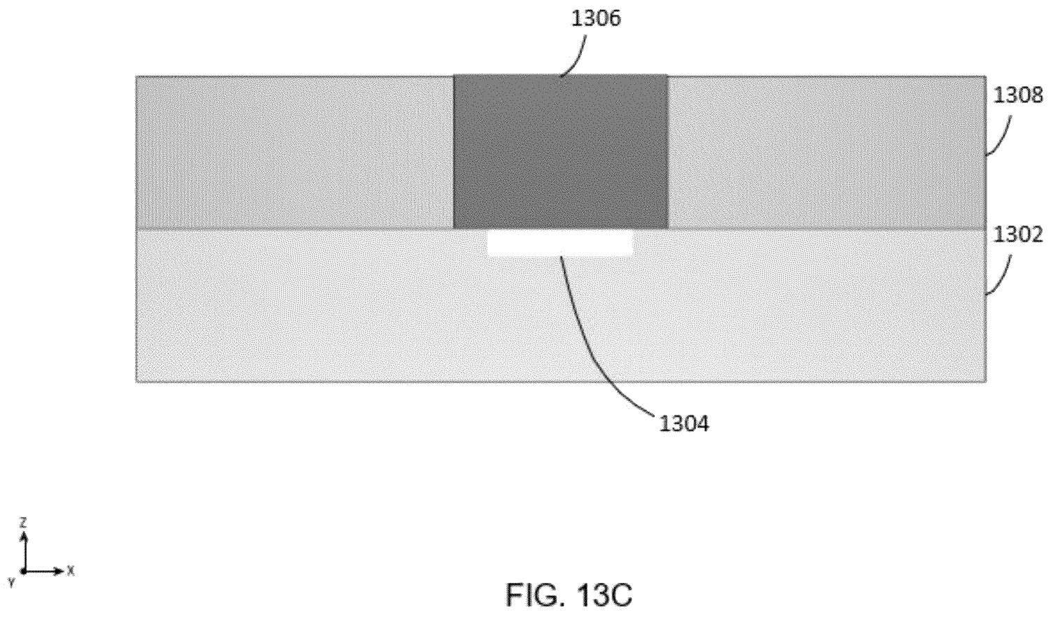

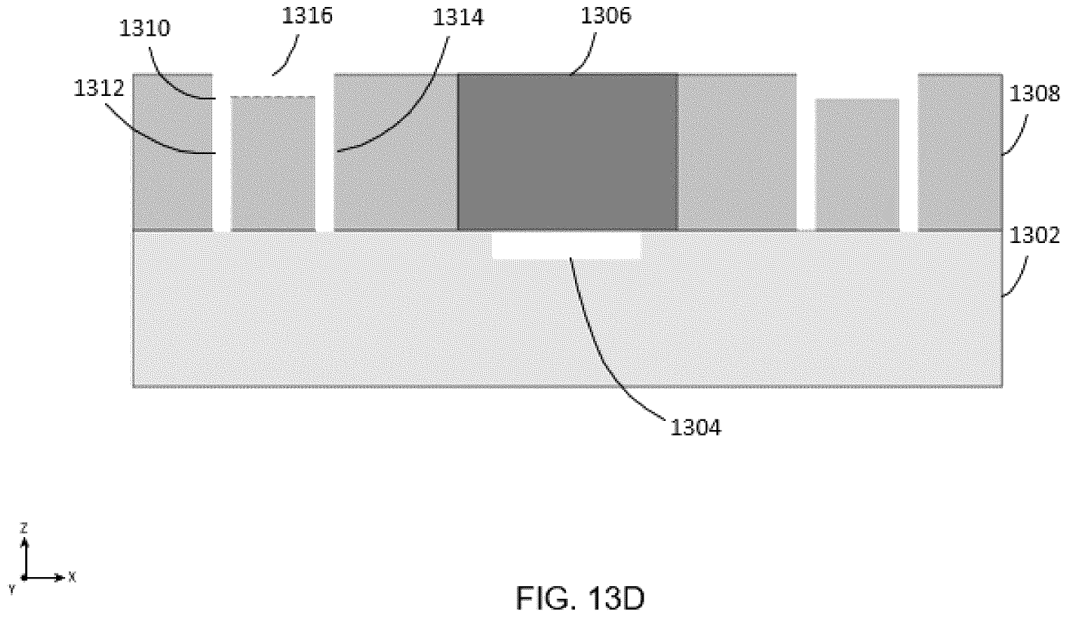

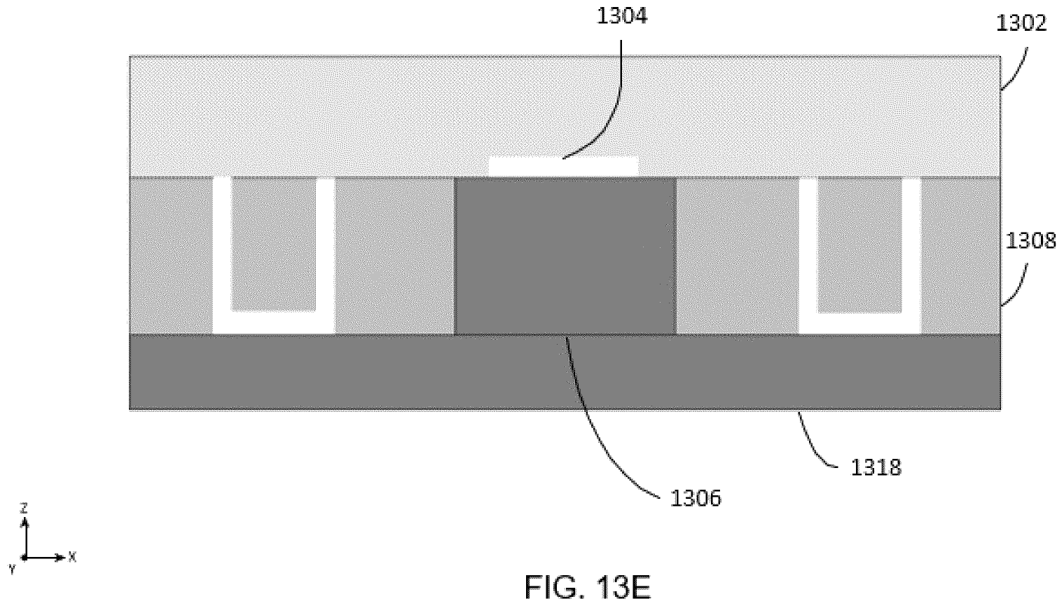

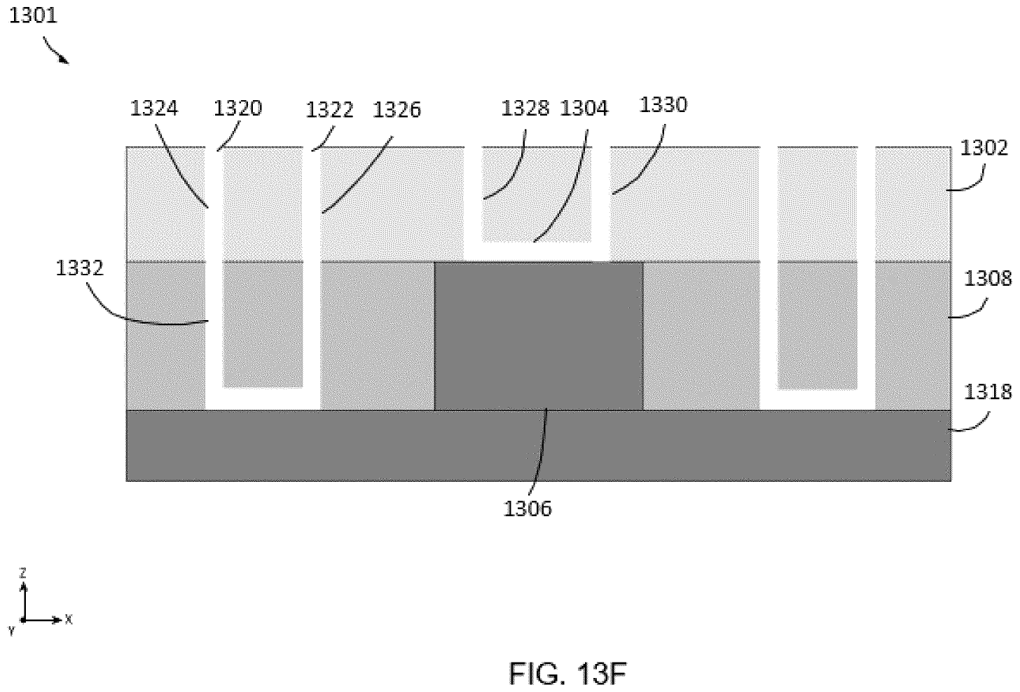

FIGS. 13A-13F are schematic partial sectional side views showing a process for manufacturing at least a part of an integrated cooling assembly 1301, in accordance with some embodiments of the disclosure. FIG. 13A displays a portion 1304 of a coolant channel formed in a carrier wafer 1302. In some embodiments, the portion 1304 of the coolant channel is formed using one or more etching processes (e.g., dry etching, wet etching, laser etching, etc.), patterning processes, and/or similar such processes.

FIG. 13B displays a first device 1306 bonded to the carrier wafer 1302. In some embodiments, the first device 1306 comprises bonding pads (e.g., DBI bonding pads) on the surface opposite the surface bonded to the carrier wafer 1302. In some embodiments, the first device 1306 undergoes one or more thinning processes. In some embodiments, the first device 1306 is temporarily bonded to the carrier wafer 1302 before the thinning process, and the carrier wafer 1302 provides support for the thinning operation and/or for substrate handling during one or more of the subsequent manufacturing operations described herein. The first device 1306 may be thinned to within 150 um or less of its final thickness.

FIG. 13C displays the first device 1306 after undergoing a reconstitution process. In some embodiments, a dielectric layer 1308 is deposited on the first device 1306 and/or the carrier wafer 1302 during the reconstitution process. In some embodiments, a grinding and/or etching process is used to remove a portion of the dielectric layer 1308 and expose the surface of the first device 1306 (including the bonding pads) that is opposite the carrier wafer 1304. The first device 1306 and/or the dielectric layer 1308 may then be polished (e.g., using a CMP process) to a desired smoothness to prepare the first device 1306 and/or the dielectric layer 1308 for bonding.

FIG. 13D displays one or more segments of one or more coolant channels formed in the dielectric layer 1308. In some embodiments, the one or more segments of the one or more coolant channels are formed using one or more etching processes (e.g., dry etching, wet etching, laser etching, etc.), patterning processes, and/or similar such processes as described herein. In some embodiments, one or more segments of the one or more coolant channels are formed using multiple steps. For example, a first segment 1310 of a coolant channel may be formed in a first region of the dielectric layer 1308 by first forming a first via 1312 and a second via 1314 in the first region of the dielectric layer 1308. After the first via 1312 and the second via 1314 are formed, a portion 1316 of the first region of the dielectric layer 1308 may be etched away to form part of the first segment 1310 of the coolant channel.

FIG. 13E displays the first device 1306 and the dielectric layer 1308 bonded to a first component 1318. In some embodiments, the first component 1318 is a die, a wafer, and/or a portion of a reconstituted wafer. In some embodiments, the first device 1306, the dielectric layer 1308, and the carrier wafer 1302 are flipped (compared to FIG. 13D), such that etched surfaces face the first component 1318 when bonded together.

FIG. 13F displays one or more segments of one or more coolant channels formed in the carrier wafer 1302. In some embodiments, the one or more segments of the one or more coolant channels are formed using one or more etching processes (e.g., dry etching, wet etching, laser etching, etc.), patterning processes, and/or similar such processes as described herein.

In some embodiments, one or more openings are formed in the carrier wafer 1302 to allow coolant fluid to flow into and out of one or more sections of a coolant channel. For example, the carrier wafer 1302 may comprise a first opening 1320 and a second opening 1322 allowing coolant fluid to flow into and out of a first coolant channel 1332. In some embodiments, the carrier wafer 1302 comprises one or more coolant channels and/or one or more sections of a coolant channel. In some embodiments, one or more sections of a coolant channel are formed within the carrier wafer 1302 to align with sections of said coolant channel formed within the dielectric layer 1308 and/or the carrier wafer 1302. For example, the carrier wafer 1302 may comprise a first section 1324 of the first coolant channel 1332 and a third section 1326 of the first coolant channel 1332. The first section 1324 of the first coolant channel 1332 and the third section 1326 of the first coolant channel 1332 may be formed within the carrier wafer 1302 to couple with a second section of the first coolant channel 1332 formed within the dielectric layer 1308. In another example, the carrier wafer 1302 may comprise a third via 1328 and a fourth via 1330. The third via 1328 and the fourth via 1330 may be formed within the carrier wafer 1302 to couple with the portion 1304 of the second coolant channel previously formed within the carrier wafer 1302.

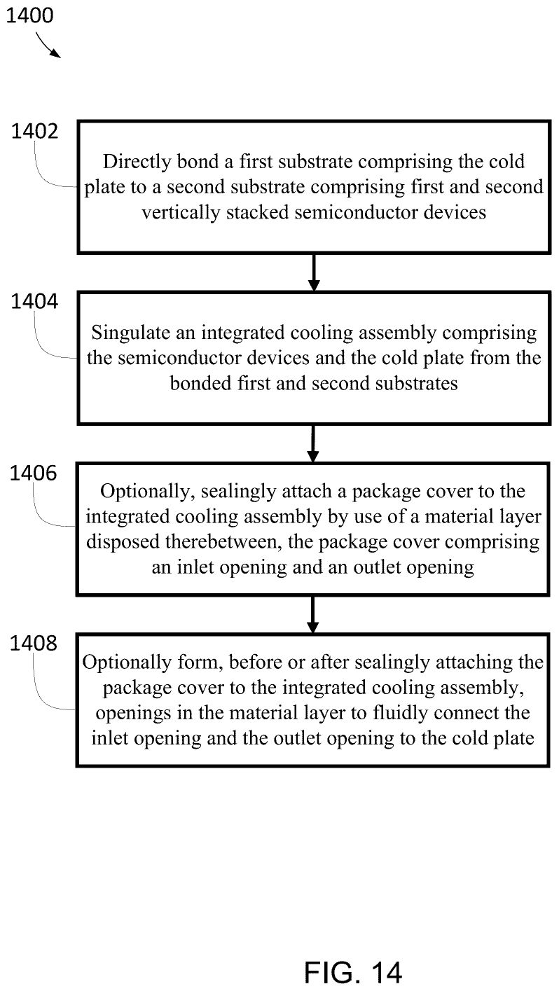

FIG. 14 is a flow diagram setting forth a method 1400 of forming an integrated cooling assembly, according to embodiments of the disclosure.

At block 1402, the method 1400 includes directly bonding a first substrate (e.g., a monocrystalline silicon wafer) comprising the cold plate 206, 306, 406, 506, 606, 906, 1006 to a second substrate (e.g., a monocrystalline silicon wafer) comprising first and second vertically stacked semiconductor devices (e.g., first device 204 and second device 230). For example, the first substrate may be etched using a patterned mask layer formed on surfaces of the respective substrates, as discussed above in relation to processes for manufacturing integrated cooling assemblies.

The second substrate may include a bulk material, and a plurality of material layers disposed on the bulk material. The bulk material may include any semiconductor material suitable for manufacturing semiconductor devices, such as silicon, silicon germanium, germanium, group III-V semiconductor materials, group II-VI semiconductor materials, silicon carbide, gallium nitride, or combinations thereof. For example, while some of the high-performance processors like CPUs, GPUs, NPUs are typically made out of silicon, some other high-power density (hence substantial heat generating) devices may comprise silicon carbide, gallium nitride, etc. For example, in some embodiments, the second substrate may include monocrystalline wafers, such as silicon wafers, vertically stacked. Each wafer may comprise a plurality of device components formed in or on the silicon wafer, and a plurality of interconnect layers formed over the plurality of device components. In other embodiments, the second substrate may comprise at least one reconstituted wafer (e.g., a substrate formed from a plurality of singulated devices embedded in a support (molding) material).

The bulk material of the second substrate may be thinned after the devices are formed using one or more backgrind, etching, and/or polishing operations that remove material from the backside. Thinning the second substrate may include using a combination of grinding and etching processes to reduce the thickness (in the Z-direction) to about 450 μm or less, such as about 201 μm or less, or about 150 μm or less. After thinning, the backside may be polished to a desired smoothness using a CMP process, and the dielectric material layer (e.g., molding) may be deposited thereon. In some embodiments, the dielectric material layer may be polished to a desired smoothness to prepare the second substrate for the bonding process.

In some embodiments, an active side is temporarily bonded to a carrier substrate before or after the thinning process. When used, the carrier substrate provides support for the thinning operation and/or for the thinned material to facilitate substrate handling during one or more of the subsequent manufacturing operations described herein.

Here, the method 1400 may include forming dielectric layers on the cold plate and the second substrate (i.e., on upper exposed surfaces of the stacked first and second semiconductor devices), and directly bonding includes forming dielectric bonds between a first dielectric material layer of the cold plate and a second dielectric material layer of the second substrate.

Generally, directly bonding the surfaces (of the dielectric material layers (e.g., silicon oxide, silicon nitride, silicon oxynitride, silicon carbonitride, oxide nitride, oxynitride, carbonitride, etc.) includes preparing, aligning, and contacting the surfaces. In some embodiments, one or more dielectric materials are deposited on a substrate prior to the bonding process. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the substrates using a CMP process. Activating and terminating the surfaces with a desired species may include exposing the surfaces to radical species formed in a plasma.

In some embodiments, the plasma is formed using a nitrogen-containing gas, (e.g., N₂, and the terminating species includes nitrogen and hydrogen). In some embodiments, the surfaces may be activated using a wet cleaning process, (e.g., by exposing the surfaces to an aqueous ammonia solution). In some embodiments, the dielectric bonds may be formed using a dielectric material layer deposited on only one of the substrates but not on both. In those embodiments, the direct dielectric bonds may be formed by contacting the deposited dielectric material layer of one substrate directly with a bulk material surface of the other substrate.

Directly forming direct dielectric bonds between the substrates includes bringing the prepared and aligned surfaces into direct contact at a temperature less than 150° C., such as less than 100° C., for example, less than 30° C., or about room temperature, e.g., between 20° C. and 30° C. Without intending to be bound by theory, it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 15 minutes. Typically, the bonds will strengthen over time even without the application of heat. Thus, in some embodiments, the method does not include heating the substrates.

After the dielectric bonds are formed, the substrates may be heated to a temperature of 150° C. or more and maintained at the elevated temperature for a duration of about 1 hour or more, such as between 8 and 24 hours, to form direct metallurgical bonds between the metal features. Suitable direct dielectric and hybrid bonding technologies that may be used to perform aspects of the methods described herein include ZiBond® and DBI®, each of which are commercially available from Adeia Holding Corp., San Jose, CA, USA.

At block 1404, the method 1400 includes singulating an integrated cooling assembly 203, 303, 403, 503, 603, 703, 803, 903, 1003 comprising vertically stacked semiconductor devices and the cold plate 206, 306, 406, 506, 606, 906, 1006 from the bonded first and second substrates.

In some embodiments, the manifolds 210, 410, 510, 610, 910, 1010 are singulated from the first and second substrates using a process that cuts or divides the first and second substrate in a vertical plane (i.e., parallel to the Z-direction). In some embodiments, the manifolds 210, 410, 510, 610, 910, 1010 are singulated using a saw or laser dicing process.

At block 1406, the method 1400 comprises sealing a package cover to the integrated cooling assembly by use of a material layer disposed therebetween, where the package cover comprises an inlet opening and an outlet opening.

At block 1408, the method 1400 comprises before or after sealing the package cover 208 to the integrated cooling assembly 203, forming openings in the material layer to fluidly connect the inlet opening and the outlet opening to the cold plate.

It is contemplated that the methods above are not limited to crystalline silicon as sloped surfaces can be formed using other methods known to those skilled in the art. Thus, in some embodiments, the cold plates may be formed of a bulk material having a substantially similar coefficient of linear thermal expansion (CTE) to the bulk material of the device, where the CTE is a fractional change in length of the material (in the X-Y plane) per degree of temperature change. In some embodiments, the CTEs of the first and second substrates are matched so that the CTE of the second substrate is within about +/−20% or less of the CTE of the first substrate, such as within +/−15% or less, within +/−10% or less, or within about +/−5% or less when measured across a desired temperature range. In some embodiments, the CTEs are matched across a temperature range from about −60° C. to about 100° C. or from about 60° C. to about 175° C. In one example embodiment, the matched CTE materials each include silicon.

The method described above advantageously provides for integrated cooling assemblies that increase cooling to semiconductor devices located at different levels (e.g., different heights in the Z-axis direction) within a device package.

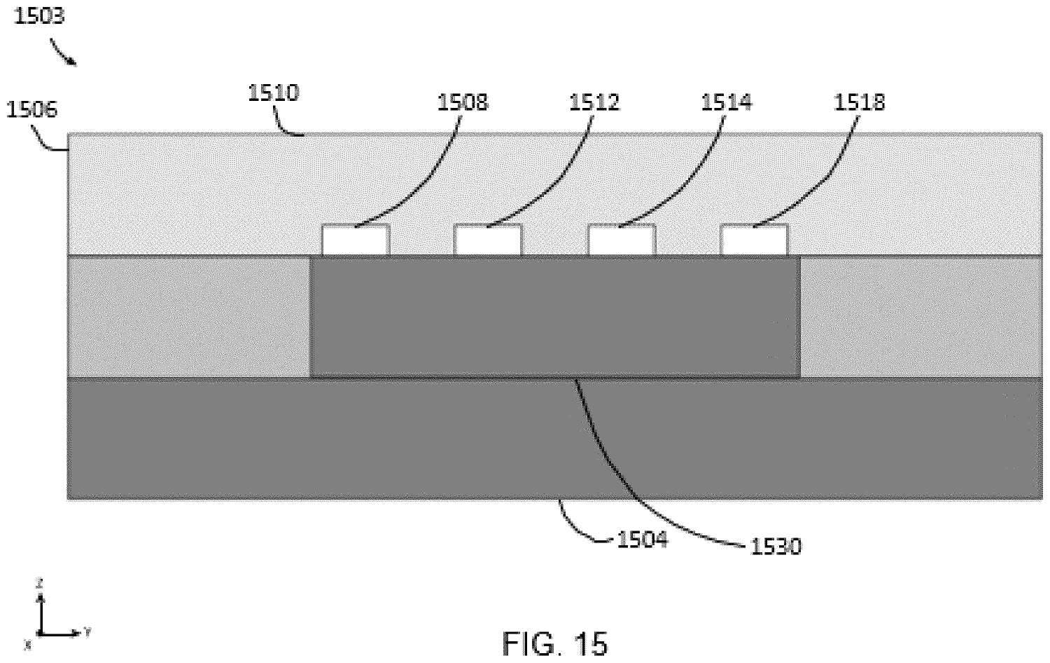

FIG. 15 is a schematic sectional view of at least a portion of an integrated cooling assembly 1503 comprising a plurality of coolant channels. The at least a portion of the integrated cooling assembly 1503 comprises a cold plate 1506, a first device 1504, and a second device 1530. Here, the second device 1530 is bonded to the first device 1504, and the cold plate 1506 is bonded to the first device 1504 and the second device 1530. As described above, the first device 1504 and/or the second device 1530 may include an active side that includes device components (e.g., transistors, resistors, capacitors, etc.) formed thereon or therein, and a non-active side (e.g., the device backside) opposite the active side. In some embodiments, the cold plate 1506 comprises a manifold 1510, one or more support features, a first coolant channel 1508, a second coolant channel 1512, a third coolant channel 1514, and a fourth coolant channel 1518. Although four coolant channels are shown, any number of coolant channels may be used. In some embodiments, the at least portion of the integrated cooling assembly 1503 comprising a plurality of coolant channels is formed using one or more of the methods described herein.

In some embodiments, the at least a portion of the integrated cooling assembly 1503 comprises coolant channel designs that are the same or similar to coolant channel designs described herein. For example, the first coolant channel 1508 may be the same or similar to the coolant channel (e.g., second coolant channel 312) described in FIG. 3. Accordingly, the first coolant channel 1508 may extend through the manifold 1510 and along a portion of the backside of the second device 1530. In another example, the second coolant channel 1512 may be the same or similar to the coolant channel (e.g., first coolant channel 408) described in FIG. 4. Accordingly, a first portion (e.g., portion 436 of FIG. 4) of the second coolant channel 1512 may extend through a support feature and along a portion of the backside of the first device 1504 and a second portion (e.g., portion 438 of FIG. 4) of the second coolant channel 1512 may extend through the manifold and along a portion of the backside of the second device 1530. In another example, the third coolant channel 1514 may be the same or similar to the coolant channel (e.g., first coolant channel 508) described in FIG. 5. Accordingly, a first portion (e.g., portion 536 of FIG. 5) of the third coolant channel 1514 may extend through a first support feature and along a first portion of the backside of the first device 1504, a second portion (e.g., portion 538 of FIG. 5) of the third coolant channel 1514 may extend through the manifold 1510 and along a portion of the backside of the second device 1530, and a third portion (e.g., portion 540 of FIG. 5) of the third coolant channel 1514 may extend through a second support feature and along a second portion of the backside of the first device 1504.

In some embodiments, all the cooling channels share the same design. For example, the first coolant channel 1508, the second coolant channel 1512, the third coolant channel 1514, and the fourth coolant channel 1518 may all share the same coolant channel design displayed in FIG. 5. In some embodiments, one or more of the cooling channels have a different design. For example, the first coolant channel 1508 and the second coolant channel 1512 may share the coolant channel design displayed in FIG. 5, while the third coolant channel 1514 and the fourth coolant channel 1518 may all share the coolant channel design displayed in FIG. 4.

In some embodiments, the cooling channels are coupled to one or more openings. In some embodiments, each cooling channel is coupled to a different opening. In embodiments having plural coolant chamber volumes and/or plural coolant channels, each coolant chamber volume and/or coolant channel may be connected between a separate inlet opening and a separate outlet opening. In such embodiments, coolant fluid may be directed to the separate inlet opening and from the separate outlet openings using a manifold disposed above the openings in the Z-axis direction. In some embodiments, one or more coolant chamber volumes and/or coolant channels may extend between a single inlet opening and a single outlet opening of the cold plate 1506, such that the coolant chamber volume(s) and/or coolant channel(s) share the same inlet and outlet openings.

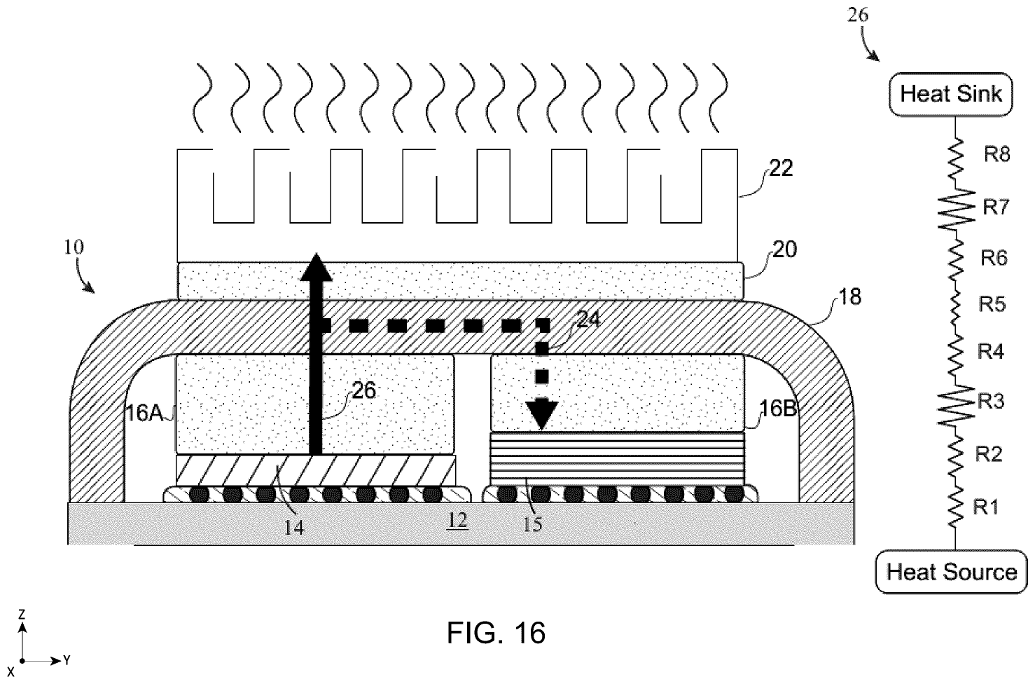

FIG. 16 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and the device stack 15 to the heat spreader 18. The device package 10 is thermally coupled to the heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 16 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirably transferred from the first device 14 having a high heat flux, such as a central processing unit (CPU) or a graphical processing unit (GPU), to the device stack 15 having low heat flux, such as memory, through the heat spreader 18.

For example, as shown in FIG. 16, each device package component and the respective interfacial boundaries therebetween have a corresponding thermal resistance that forms heat transfer path 26 (illustrated by arrow 26 in FIG. 16). The right-hand side of FIG. 16 illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26, and R5 may account for 5% or more. R1 of the first device 14 and R2, R4, R6, and R8 of the interfaces account for the remaining cumulative thermal resistance. Accordingly, embodiments described herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures herein.

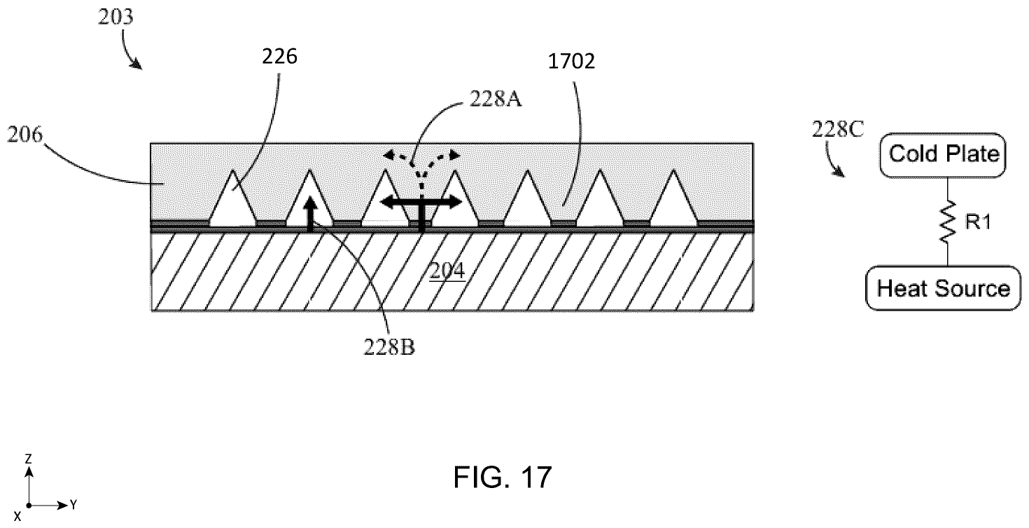

FIG. 17 is a schematic sectional view in the Y-Z plane of the integrated cooling assembly 203. In FIG. 17, the cold plate 206 comprises a patterned side that faces towards the semiconductor device 204 and an opposite side that faces towards the package cover 208 (not shown). The patterned side comprises a coolant chamber volume having plural coolant channels 226, which extend laterally between the inlet and outlet openings of the cold plate 206. Each coolant channel 226 comprises cavity sidewalls that define a corresponding coolant channel 226. Portions of the cold plate 206 between the cavity sidewalls form support features 1702. The support features 1702 provide structural support to the integrated cooling assembly 203 and disrupt laminar fluid flow at the interface of the coolant and the device backside 220, resulting in increased heat transfer therebetween. Furthermore, by introducing plural coolant channels 226 to define separate coolant flow paths, an internal surface area of the cold plate 206 is increased, which further increases the efficiency of heat transfer.

In FIG. 17, arrows 228A and 228B illustrate two different heat transfer paths in the integrated cooling assembly 203. A first heat transfer path illustrated by arrow 228B shows heat generated by the semiconductor device 204 transferring directly from the semiconductor material of the semiconductor device 204 to coolant fluid flowing through the cold plate 206. A second heat transfer path illustrated by arrows 228A shows heat generated by the semiconductor device 204 being transferred from semiconductor material (e.g., silicon material) of the semiconductor device 204 to semiconductor material (e.g., silicon material) of the cold plate 206 structure, propagated throughout the semiconductor material of the cold plate 206 structure (shown as dashed lines), and being transferring into coolant fluid flowing through the cold plate 206. A thermal resistance of the first and second heat transfer paths 228A, 228B is illustrated by heat transfer path 228C, which is shown as thermal resistance R1 between a heat source and a cold plate. Here, R1 is the thermal resistance of the bulk semiconductor material of the semiconductor device 204. It can be seen that the heat transfer path 228C of the integrated cooling assembly 203 is reduced compared to the heat transfer path 26 of the device package 10 of FIG. 1, due to the direct bonding discussed above.

In some embodiments, the cold plate 206 may be attached to the semiconductor device 204 using a hybrid bonding technique, where bonds are formed between dielectric material layers and between metal features, such as between first metal pads and second metal pads, disposed in the dielectric material layers.

Suitable dielectrics that may be used as the dielectric material layers include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometers or less, 1 micrometer or less, 500 nm or less, such as 100 nm or less, or 50 nm or less. The dielectric layer material and thickness may be optimized for lower thermal resistance between the die and the cold plate.

The cold plate 206 may be formed of any suitable material that has sufficient structural strength to withstand the desired pressures of coolant flowing into the coolant channels 226. For example, the cold plate 206 may be formed of semiconductor material like silicon or other engineered materials like glass. In other examples, the cold plate 206 may be formed of a material selected from a group comprising polymers, metals, ceramics, or composites thereof. In some embodiments, the cold plate 206 may be formed of stainless steel (e.g., from a stainless-steel metal sheet) or a sapphire plate.

In some embodiments, the cold plate 206 may be formed of a bulk material having a substantially similar coefficient of linear thermal expansion (CTE) to the bulk material of the substrate 202 and/or the semiconductor device 204, where the CTE is a fractional change in length of the material (in the X-Y plane) per degree of temperature change. In some embodiments, the CTEs of the cold plate 206, the substrate 202, and/or the semiconductor device 204 are matched so that the CTE of the substrate 204 and/or the semiconductor device 204 is within about +/−20% or less of the CTE of the cold plate 206, such as within +/−15% or less, within +/−10% or less, or within about +/−5% or less when measured across a desired temperature range. In some embodiments, the CTEs are matched across a temperature range from about −60° C. to about 100° C. or from about −60° C. to about 175° C. In one example embodiment, the matched CTE materials each include silicon.

In some embodiments, the cold plate 206 may be formed of a material having a substantially different CTE from the semiconductor device 204, e.g., a CTE mismatched material. In such embodiments, the cold plate 206 may be attached to the semiconductor device 204 by a compliant adhesive layer (not shown) or a molding material that absorbs the difference in expansion between the cold plate 206 and the semiconductor device 204 across repeated thermal cycles.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure. Only the claims that follow are meant to set bounds as to what the present disclosure includes.

1. A device package comprising:
a cooling assembly comprising a first semiconductor device, a cold plate, and a second semiconductor device attached therebetween, wherein the cold plate comprises:
a manifold attached to the second semiconductor device, the manifold comprising an inlet opening and an outlet opening;
a support feature extending downwardly from the manifold to the first semiconductor device; and
a coolant channel coupling the inlet opening and the outlet opening, wherein the coolant channel extends through a portion of the support feature proximate to the first semiconductor device.

2. The device package of claim 1, wherein the coolant channel further extends through a portion of the manifold proximate to the second semiconductor device.

3. The device package of claim 1, wherein the support feature comprises a portion of a reconstituted wafer.

4. The device package of claim 1, wherein the support feature comprises a dummy die.

5. The device package of claim 1, further comprising a portion of a reconstituted wafer around the second semiconductor device.

6. The device package of claim 1, wherein the manifold further comprises:
an additional inlet opening and an additional outlet opening; and
an additional coolant channel coupling the additional inlet opening and the additional outlet opening, wherein the additional coolant channel extends through a portion of the manifold proximate to the second semiconductor device.

7. The device package of claim 1, wherein:
the first semiconductor device defines a first level; and
the second semiconductor device defines a second level vertically adjacent to the first level.

8. The device package of claim 1, wherein the manifold is attached to the second semiconductor device by direct dielectric bonds.

9. The device package of claim 1, wherein the support feature is attached to the first semiconductor device by direct dielectric bonds.

10. The device package of claim 1, wherein the first semiconductor device is attached to the second semiconductor device by direct dielectric bonds.

11. A device package comprising:
a first semiconductor device having a first thickness;
a second semiconductor device laterally adjacent to the first semiconductor device and having a second thickness different from the first thickness; and
a cold plate comprising:
a manifold extending laterally across and disposed above the semiconductor devices;
a first support feature attached between the manifold and the first semiconductor device;
a second support feature attached between the manifold and the second semiconductor device; and
first and second coolant channels extending through the first and second support features, respectively, wherein the first coolant channel is proximate to the first semiconductor device and the second coolant channel is proximate to the second semiconductor device.

12. The device package of claim 11, wherein the cold plate further comprises a first inlet opening and a first outlet opening.

13. The device package of claim 12, wherein:
the first coolant channel couples the first inlet opening to the second coolant channel; and
the second coolant channel couples the first coolant channel to the first outlet opening.

14. The device package of claim 12, wherein the first coolant channel couples the first inlet opening and the first outlet opening.

15. The device package of claim 14, wherein:
the cold plate further comprises a second inlet opening and a second outlet opening; and the second coolant channel couples the second inlet opening and the second outlet opening.

16. The device package of claim 11, wherein at least one support feature comprises a portion of a reconstituted wafer.

17. The device package of claim 11, wherein at least one support feature comprises a dummy die.

18. The device package of claim 11, further comprising a portion of a reconstituted wafer around the first semiconductor device.

19. The device package of claim 11, wherein the cold plate is attached to the first semiconductor device and/or the second semiconductor device by direct dielectric bonds.

20. The device package of claim 11, wherein the cold plate is attached to the second semiconductor device by direct dielectric bonds.

21.-30. (canceled)
